(19) United States
(12) Patent Application Publication
(10) Pub. No.: US 2025/0081846 A1
(43) Pub. Date: Mar. 6, 2025

(54) Organic Light Emitting Device and Display Apparatus

(71) Applicant: BOE Technology Group Co., Ltd., Beijing (CN)

(72) Inventors: Rongrong GAO, Beijing (CN); Dan WANG, Beijing (CN); Lei CHEN, Beijing (CN); Lixia QIU, Beijing (CN); Yuqian SUN, Beijing (CN)

(21) Appl. No.: 18/279,218

(22) PCT Filed: Nov. 29, 2022
(86) PCT No.: PCT/CN2022/135104

§ 371 Date: Aug. 29, 2023

(51) Int. Cl. H10K 85/60; H10K 50/15; H10K 50/18; H10K 101/40

(52) U.S. Cl. CPC H10K 85/6572; H10K 50/156; H10K 50/181; H10K 85/636; H10K 85/6574; H10K 85/6576; H10K 2101/40

(57) ABSTRACT

An organic light emitting device includes an anode, a cathode, and a first hole transport layer and a first light emitting layer arranged between the anode and the cathode, wherein the first hole transport layer is located between the first light emitting layer and the anode; the first hole transport layer at least includes a first hole sublayer and a second hole sublayer; a material of the first hole sublayer includes a first material and a second material, and a material of the second hole sublayer includes at least one of the first material and the second material.

### CROSS-REFERENCE TO RELATED APPLICATION

This application is a national stage application of PCT Application No. PCT/CN2022/135104, which is filed on Nov. 29, 2022 and entitled “Organic Light Emitting Device and Display Apparatus”, the content of which should be regarded as being incorporated herein by reference.

### TECHNICAL FIELD

The present disclosure relates to, but is not limited to, the field of display technology, in particular to a stacked organic light emitting device and a display apparatus.

### BACKGROUND

An Organic Light Emitting Diode (OLED) is an active light emitting device having advantages such as light emission, ultra-thinness, wide viewing angle, high brightness, high contrast, low power consumption, extremely high response speed, and has gradually become the next generation display technology with great development prospects.

An OLED includes an anode, a cathode, and a light emitting layer arranged between the anode and the cathode. A light emitting principle of the OLED is to inject holes and electrons into the light emitting layer from the anode and the cathode respectively. When the electrons and the holes meet in the light emitting layer, the electrons and the holes recombine to produce excitons. When transforming from an excited state to a ground state, these excitons emit light. In order to inject the electrons and the holes from electrodes into the light emitting layer smoothly under a relatively low driving voltage, a hole injection layer and a hole transport layer are arranged between the anode and the light emitting layer, and an electron injection layer and an electron transport layer are arranged between the cathode and the light emitting layer. In order to make the OLED achieve better light emitting efficiency and realize low voltage and long life, the design of the hole injection layer is more important.

### SUMMARY

The following is a summary of subject matter described herein in detail. The summary is not intended to limit the protection scope of claims.

An organic light emitting device and a display apparatus.

An embodiment of the present disclosure provides an organic light emitting device, including an anode, a cathode, and a first hole transport layer and a first light emitting layer arranged between the anode and the cathode, wherein the first hole transport layer is located between the first light emitting layer and the anode; the first hole transport layer at least includes a first hole sublayer and a second hole sublayer; a material of the first hole sublayer includes a first material and a second material, and a material of the second hole sublayer includes at least one of the first material and the second material; and

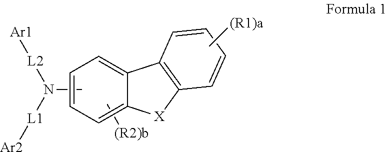

in Formula 1:
X is O, S, C, or N;
L1 and L2 are each independently a direct bond, each independently a substituted or unsubstituted C6-C60 aryl;
Ar1 and Ar2 are each independently hydrogen, deuterium, a halogen group, nitrile, nitro, hydroxyl, carbonyl, an ester group, imide, amino, a substituted or unsubstituted silyl, a substituted or unsubstituted boron, a substituted or unsubstituted alkyl, a substituted or unsubstituted cycloalkyl, a substituted or unsubstituted alkoxy, a substituted or unsubstituted aryloxy, a substituted or unsubstituted alkylthio, a substituted or unsubstituted arylthio, a substituted or unsubstituted alkylsulfonyl, a substituted or unsubstituted arylsulfonyl, a substituted or unsubstituted alkenyl, a substituted or unsubstituted arylalkyl, a substituted or unsubstituted arylalkenyl, a substituted or unsubstituted alkylaryl, a substituted or unsubstituted alkylamine, a substituted or unsubstituted arylalkylamine, a substituted or unsubstituted heteroarylamine, a substituted or unsubstituted arylamine, a substituted or unsubstituted arylheteroarylamine, a substituted or unsubstituted arylphosphine, a substituted or unsubstituted phosphine oxide group, a substituted or unsubstituted aryl, or a substituted or unsubstituted heterocyclic group; or represented by Formula 2 below:

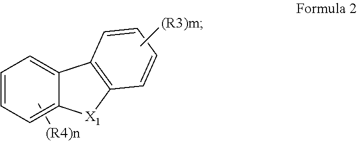

R1, R2, R3 and R4 are each independently selected from deuterium, a halogen group, cyano, C3-C20 heteroaryl, C6-C20 aryl, C3-C12 trialkylsilyl, C18-C30 triarylsilyl, C1-C5 alkyl, C1-C10 haloalkyl, C3-C10 cycloalkyl, C2-C10 heterocycloalkyl, C5-C10 cycloalkenyl, C4-C10 heterocycloalkenyl, C1-C10 alkoxy, C1-C10 alkylthio, C6-C18 aryloxy, C6-C18 arylthio, C6-C24 phosphoroxy, C6-C18 alkylsulfonyl, C3-C18 trialkylphosphine, C3-C18 trialkylboron; or optionally bonded to adjacent groups to form a ring;
a, b, m and n are each independently an integer of 0-4.

In an exemplary embodiment of the present disclosure, the first hole sublayer is located between the second hole sublayer and the anode.

In an exemplary embodiment of the present disclosure, a difference between a LUMO energy level of the first material and a HOMO energy level of the second material is between −0.3 eV and 1.0 eV.

In an exemplary embodiment of the present disclosure, the organic light emitting device further includes a first electron block layer located between the first light emitting layer and the first hole transport layer, and a difference between a HOMO energy level of a material of the second hole sublayer and a LUMO energy level of the first electron block layer is less than or equal to 0.4 eV.

In an exemplary embodiment of the present disclosure, a mobility of a material of the second hole sublayer is greater than a mobility of the first electron block layer.

In an exemplary embodiment of the present disclosure, a difference between the LUMO energy level of the first electron block layer and a HOMO energy level of the first light emitting layer is less than or equal to 0.4 eV.

In an exemplary embodiment of the present disclosure, the first electron block layer includes a first block sublayer, or, the first electron block layer includes a first block sublayer and a second block sublayer, the second block sublayer is located between the first block sublayer and the first light emitting layer, and a material of the first block sublayer is different from a material of the second block sublayer.

In an exemplary embodiment of the present disclosure, the organic light emitting device further includes a hole injection layer located between the first hole transport layer and the anode and having a resistivity greater than or equal to 100 Ω·m.

In an exemplary embodiment of the present disclosure, the organic light emitting device further includes a charge generation layer, a second hole transport layer and a second light emitting layer, the charge generation layer is located on a side of the first light emitting layer close to the cathode, the second hole transport layer is located on a side of the charge generation layer close to the cathode, and the second light emitting layer is located between the second hole transport layer and the cathode; and the second hole transport layer includes at least a third hole sublayer, and a material of the third hole sublayer includes the first material and the second material.

In an exemplary embodiment of the present disclosure, the third hole sublayer is located between the second light emitting layer and the charge generation layer.

In an exemplary embodiment of the present disclosure, a mobility M₂ of the material of the second hole sublayer and a mobility M₄ of the material of the third hole sublayer meet the following condition:

10⁻¹ cm²/Vs≤M₂/M₄≤10 cm²/Vs

In an exemplary embodiment of the present disclosure, the organic light emitting device further includes a second electron block layer, the second electron block layer includes a third block sublayer, or, the second electron block layer includes a third block sublayer and a fourth block sublayer, the second electron block layer is located between the second light emitting layer and the second hole transport layer, and a difference between a HOMO energy level of the material of the third hole sublayer and a LUMO energy level of the second electron block layer is less than or equal to 0.4 eV.

In an exemplary embodiment of the present disclosure, a mobility of the material of the third hole sublayer is greater than a mobility of the second electron block layer.

In an exemplary embodiment of the present disclosure, a difference between a LUMO energy level of the fourth block sublayer and a HOMO energy level of the second light emitting layer is less than or equal to 0.4 eV.

In an exemplary embodiment of the present disclosure, the second electron block layer includes a third block sublayer, or, the second electron block layer includes a third block sublayer and a fourth block sublayer, the fourth block sublayer is located between the third block sublayer and the second light emitting layer, and a material of the third block sublayer is different from a material of the fourth block sublayer.

In an exemplary embodiment of the present disclosure, the compound of Formula 1 is selected from one or more of the following compounds:

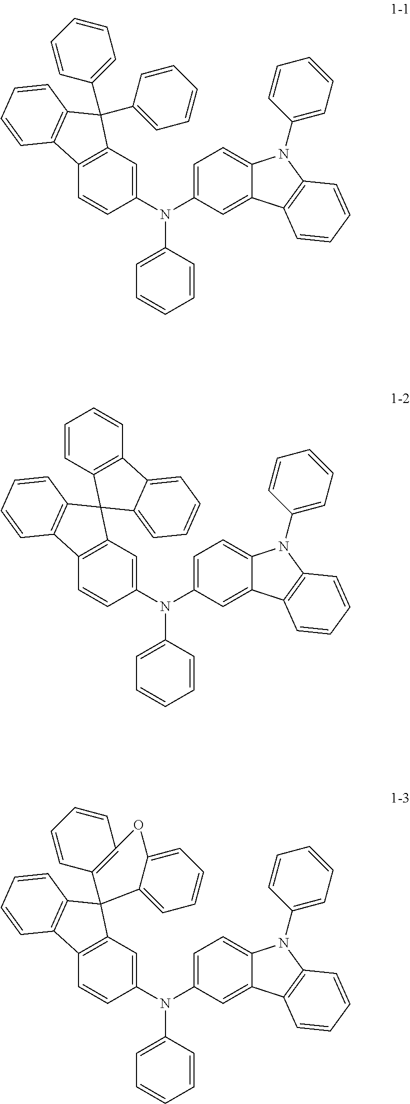 [SMILES: c1ccc(N(c2ccc3c(c2)C(c2ccccc2)(c2ccccc2)c2ccccc2-3)c2ccc3c(c2)c2ccccc2n3-c2ccccc2)cc1 ; c1ccc(N(c2ccc3c(c2)C2(c4ccccc4-c4ccccc42)c2ccccc2-3)c2ccc3c(c2)c2ccccc2n3-c2ccccc2)cc1 ; c1ccc(N(c2ccc3c(c2)C2(c4ccccc4Oc4ccccc42)c2ccccc2-3)c2ccc3c(c2)c2ccccc2n3-c2ccccc2)cc1]

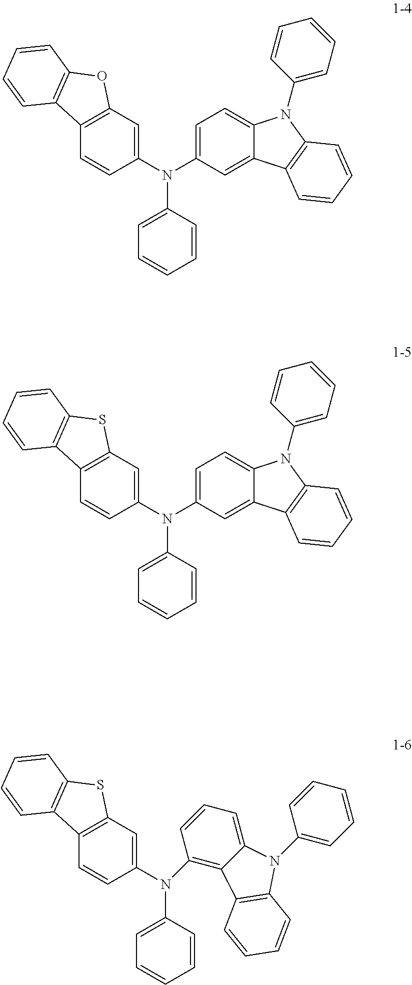 [SMILES: c1ccc(N(c2ccc3c(c2)oc2ccccc23)c2ccc3c(c2)c2ccccc2n3-c2ccccc2)cc1 ; c1ccc(N(c2ccc3c(c2)sc2ccccc23)c2ccc3c(c2)c2ccccc2n3-c2ccccc2)cc1 ; c1ccc(N(c2ccc3c(c2)sc2ccccc23)c2cccc3c2c2ccccc2n3-c2ccccc2)cc1]

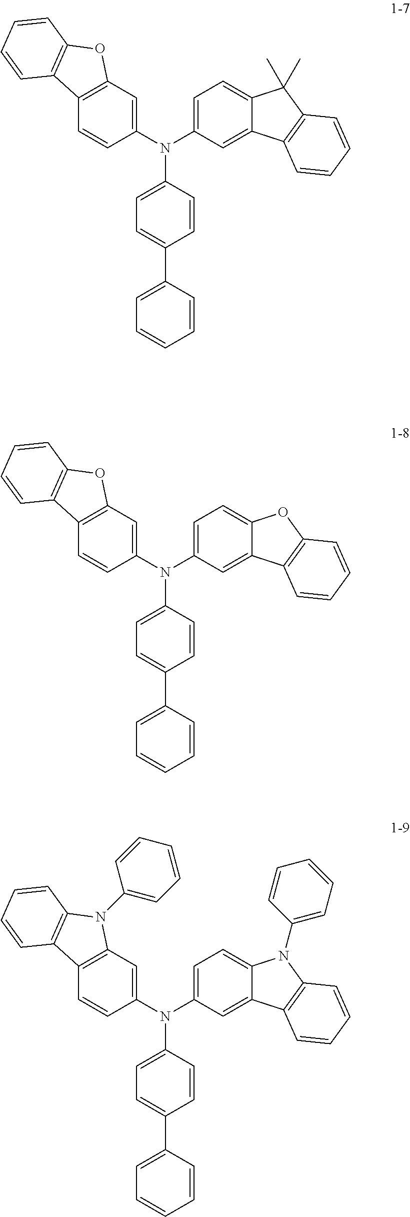 [SMILES: CC1(C)c2ccccc2-c2cc(N(c3ccc(-c4ccccc4)cc3)c3ccc4c(c3)oc3ccccc34)ccc21 ; c1ccc(-c2ccc(N(c3ccc4c(c3)oc3ccccc34)c3ccc4oc5ccccc5c4c3)cc2)cc1 ; c1ccc(-c2ccc(N(c3ccc4c(c3)c3ccccc3n4-c3ccccc3)c3ccc4c5ccccc5n(-c5ccccc5)c4c3)cc2)cc1]

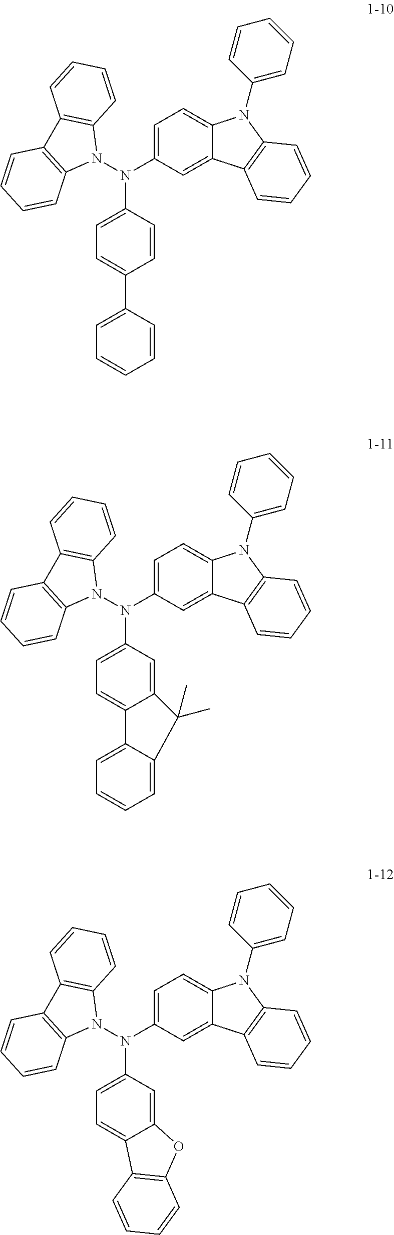 [SMILES: c1ccc(-c2ccc(N(c3ccc4c(c3)c3ccccc3n4-c3ccccc3)n3c4ccccc4c4ccccc43)cc2)cc1 ; CC1(C)c2ccccc2-c2ccc(N(c3ccc4c(c3)c3ccccc3n4-c3ccccc3)n3c4ccccc4c4ccccc43)cc21 ; c1ccc(-n2c3ccccc3c3cc(N(c4ccc5c(c4)oc4ccccc45)n4c5ccccc5c5ccccc54)ccc32)cc1]

In an exemplary embodiment of the present disclosure, the second material includes, but is not limited to, a compound having a structure of formula 3:

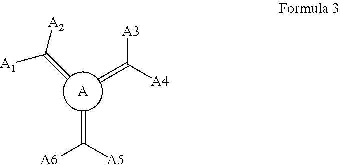

in Formula 3:
A1-A6 are each independently a halogen, a substituted or unsubstituted cyano, a substituted or unsubstituted aryl, a substituted or unsubstituted heteroaryl, and the aryl substituted by an electron-deficient group or the heteroaryl substituted by an electron-deficient group; and
A is a three-membered ring, a four-membered ring, a five-membered ring, or a six-membered ring.

In an exemplary embodiment of the present disclosure, the compound of Formula 3 is selected from one or more of the following compounds:

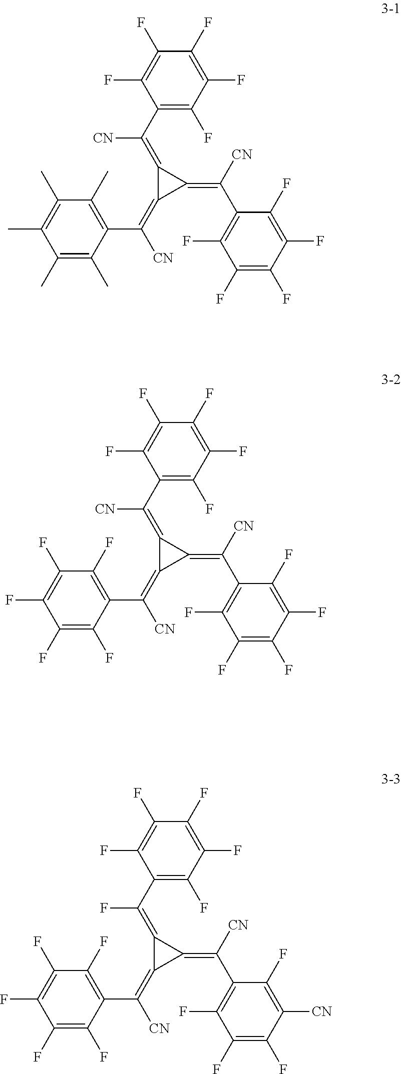

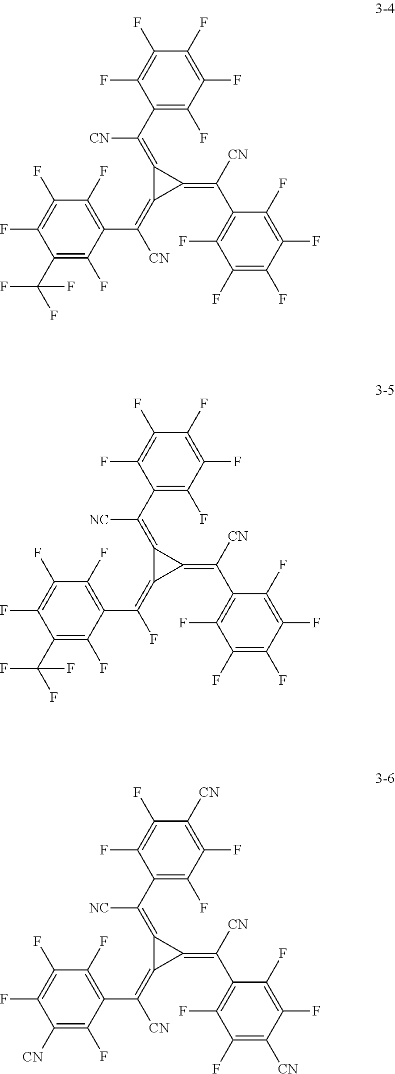

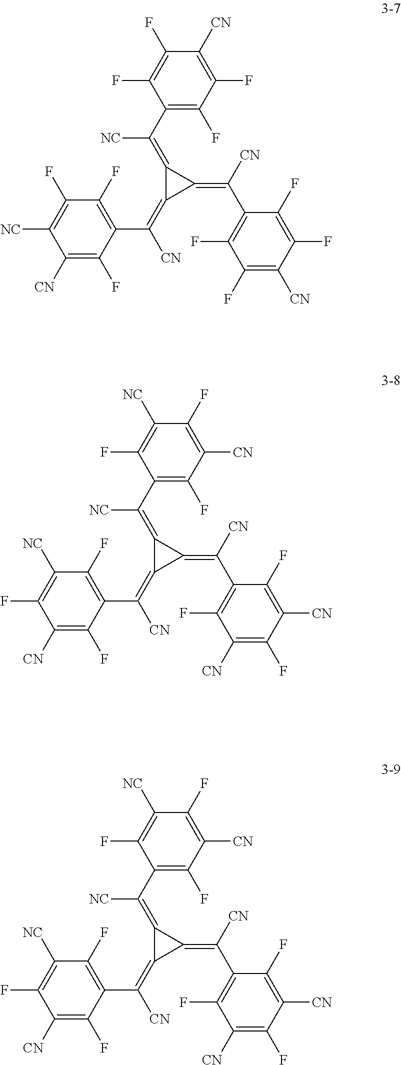

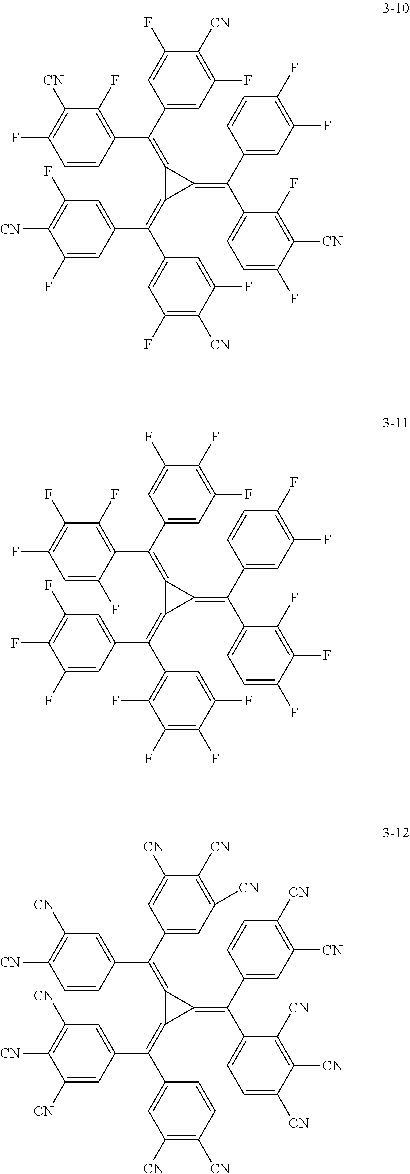

In an exemplary embodiment of the present disclosure, the electron block layer includes, but is not limited to, a compound having a structure of Formula 4:

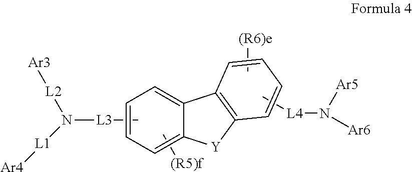

in Formula 4, Ar3, Ar4, Ar5 and Ar6 are each independently a substituted or unsubstituted aryl, a substituted or unsubstituted heteroaryl;
L1, L2, L3 and L4 are each independently a direct bond, each independently a substituted or unsubstituted C6-C60 aryl;
R5 and R6 are each independently selected from deuterium, a halogen group, cyano, C3-C20 heteroaryl, C6-C20 aryl, C3-C12 trialkylsilyl, C18-C30 triarylsilyl, C1-C5 alkyl, C1-C10 haloalkyl, C3-C10 cycloalkyl, C2-C10 heterocycloalkyl, C5-C10 cycloalkenyl, C4-C10 heterocycloalkenyl, C1-C10 alkoxy, C1-C10 alkylthio, C6-C18 aryloxy, C6-C18 arylthio, C6-C24 phosphoroxy, C6-C18 alkylsulfonyl, C3-C18 trialkylphosphine, C3-C18 trialkylboron; or optionally bonded to adjacent groups to form a ring; and
Ar3, Ar4, Ar5 and Ar6 are each independently the following groups:

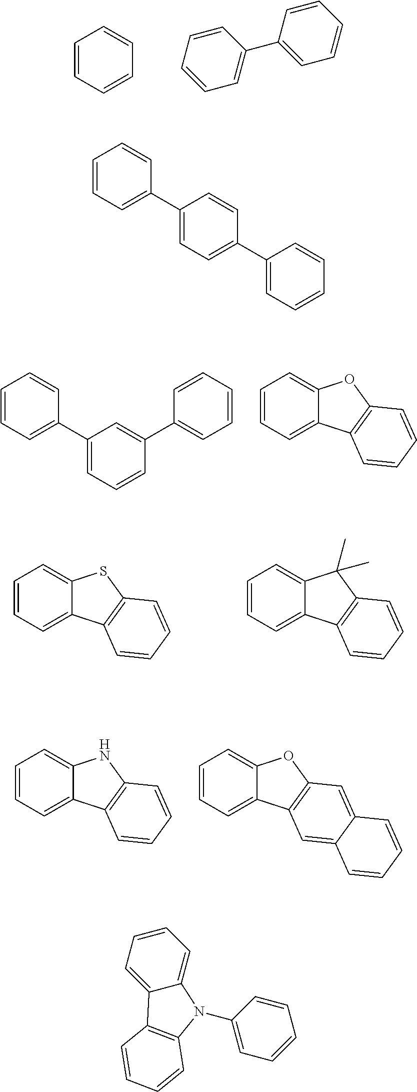

An embodiment of the present disclosure provides a display apparatus, including the organic light emitting device described above.

Other aspects may be understood upon reading and understanding the drawings and detailed description.

### BRIEF DESCRIPTION OF DRAWINGS

Accompanying drawings are intended to provide a further understanding of technical solutions of the present disclosure and form a part of the specification, and are used to explain the technical solutions of the present disclosure together with embodiments of the present disclosure, and do not form limitations on the technical solutions of the present disclosure. Shapes and sizes of various components in the drawings do not reflect actual scales, but are only intended to schematically illustrate contents of the present disclosure.

FIG. 1 is a schematic diagram of structure of an OLED display apparatus.

FIG. 2 is a schematic diagram of a planar structure of a display area of a display substrate.

FIG. 3 is a schematic diagram of a sectional structure of a display substrate.

FIG. 4 is a schematic diagram of structure of an exemplary organic light emitting device according to an example of the present disclosure.

FIG. 5 is a schematic diagram of structure of another exemplary organic light emitting device according to an example of the present disclosure.

FIG. 6A and FIG. 6B are schematic diagrams of structure of further exemplary organic light emitting devices according to an example of the present disclosure.

FIG. 7 is a schematic diagram of structure of a further exemplary organic light emitting device according to an example of the present disclosure.

FIG. 8A and FIG. 8B are schematic diagrams of structure of further exemplary organic light emitting devices according to an example of the present disclosure.

FIG. 9 is a schematic diagram of structure of a further exemplary organic light emitting device according to an example of the present disclosure.

FIG. 10 is a schematic diagram of structure of a further exemplary organic light emitting device according to an example of the present disclosure.

FIG. 11 is a schematic diagram of structure of a further exemplary organic light emitting device according to an example of the present disclosure.

FIG. 12 is an exemplary crosstalk phenomenon.

FIG. 13 is an exemplary crosstalk-free spectrum of a device of the present disclosure.

### DESCRIPTION OF REFERENCE SIGNS IN THE DRAWING

10—anode; 20—first hole transport layer; 21—first hole sublayer; 22—second hole sublayer; 20′—second hole transport layer; 21′—third hole sublayer; 30—first electron block layer; 31—first block sublayer; 32—second block sublayer; 30′—second electron block layer; 31′—third block sublayer; 32′—fourth block sublayer; 40—first light emitting layer; 40′—second light emitting layer; 41—light emitting layer 1; 42—light emitting layer 2; 43—light emitting layer 3; 41′—light emitting layer 1; 42′—light emitting layer 2; 43′—light emitting layer 3; 50—hole block layer; 60—charge generation layer; 61—N-type charge generation layer; 62—P-type charge generation layer; 80—electron transport layer; 89—electron injection layer; 90—cathode; 101—base substrate; 102—drive circuit layer; 103—light emitting device; 104—encapsulation layer; 201—first insulation layer; 202—second insulation layer; 203—third insulation layer; 204—fourth insulation layer; 205—planarization layer; 210—drive transistor; 211—storage capacitor; 301—anode; 302—pixel definition layer; 303—organic light emitting layer; 304—cathode; 401—first encapsulation layer; 402—second encapsulation layer; and 403—third encapsulation layer.

### DETAILED DESCRIPTION

Implementations herein may be implemented in multiple different forms. Those of ordinary skills in the art may readily appreciate a fact that the implementations and contents may be varied into various forms without departing from the spirit and scope of the present disclosure. Therefore, the present disclosure should not be explained as being limited to contents described in following implementations only. The embodiments in the present disclosure and features in the embodiments may be combined randomly with each other if there is no conflict.

In the accompanying drawings, a size of a constituent element, and a thickness of a layer or a region may be sometimes exaggerated for clarity. Therefore, any one implementation of the present disclosure is not necessarily limited to dimensions shown in the drawings, and the shapes and sizes of the components in the accompanying drawings do not reflect actual scales. In addition, the accompanying drawings schematically show an ideal example, and any one implementation of the present disclosure is not limited to the shapes, values, or the like shown in the accompanying drawings.

Ordinal numerals such as “first”, “second”, and “third” herein are set to avoid confusion between constituent elements, but are not intended to limit in terms of quantity.

Herein, for convenience, wordings indicating orientations or positional relationships, such as “center”, “upper”, “lower”, “front”, “back”, “vertical”, “horizontal”, “top”, “bottom”, “inside”, “outside”, are used to describe the positional relationships between the constituent elements with reference to the accompanying drawings, and are merely for facilitating describing the implementations and simplifying the specification, rather than indicating or implying that the referred apparatuses or elements must have particular orientations, and be constructed and operated in particular orientations. Thus, they cannot be construed as a limitation on the present disclosure. The positional relationships between the constituent elements can be appropriately changed according to directions according to which the constituent elements are described. Therefore, appropriate replacements can be made according to situations without being limited to the wordings described in the specification.

Herein, unless otherwise specified and defined explicitly, terms “mount”, “mutually connect”, “connect” should be understood in a broad sense. For example, a connection may be a fixed connection, or a detachable connection, or an integrated connection. It may be a mechanical connection or an electrical connection. It may be a direct mutual connection, or an indirect connection through middleware, or an internal communication between two elements. Those of ordinary skills in the art may understand meanings of the above-mentioned terms in the present disclosure according to situations.

Herein, a transistor refers to an element at least including three terminals, i.e., a gate electrode, a drain electrode, and a source electrode. A transistor has a channel region between a drain electrode (or referred to as a drain electrode terminal, a drain region, or a drain electrode) and a source electrode (or referred to as a source electrode terminal, a source region, or a source electrode), and a current can flow through the drain electrode, the channel region, and the source electrode. Herein, the channel region refers to a region through which the current mainly flows.

Herein, a first electrode may be the drain electrode and a second electrode may be the source electrode; or, the first electrode may be the source electrode and the second electrode may be the drain electrode. Functions of the “source electrode” and the “drain electrode” are sometimes interchangeable with each other in a case that transistors with opposite polarities are used or a current direction changes during circuit operation. Therefore, the “source electrode” and the “drain electrode” are interchangeable herein.

Herein, an “electrical connection” includes a case that constituent elements are connected together through an element with certain electrical function. The “element with certain electrical function” is not particularly limited as long as electrical signals may be sent and received between the connected constituent elements. For example, the “element with certain electrical function”, for example, may be an electrode or wiring, or a switching element such as a transistor, or another functional element, such as a resistor, an inductor, and a capacitor.

Herein, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

Herein, a “film” and a “layer” are interchangeable. For example, a “conductive layer” may be replaced with a “conductive film” sometimes. Similarly, an “insulation film” may be replaced with an “insulation layer” sometimes.

“About” herein refers to that a boundary is defined not so strictly and numerical values within process and measurement error ranges are allowed.

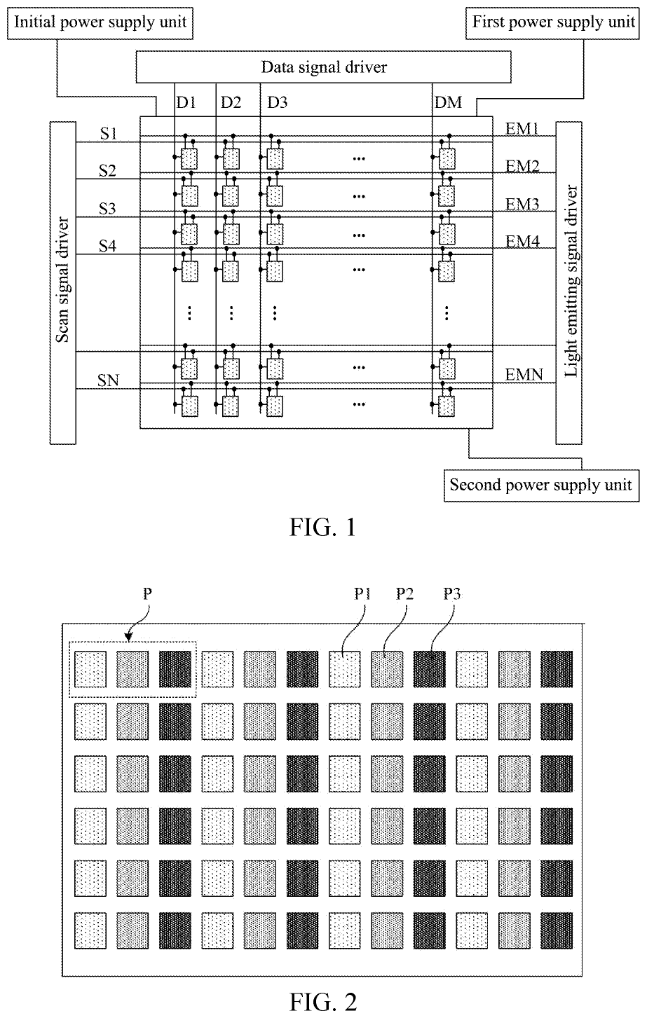

FIG. 1 is a schematic diagram of structure of an OLED display apparatus. As shown in FIG. 1, the OLED display apparatus may include a scan signal driver, a data signal driver, a light emitting signal driver, an OLED display substrate, a first power supply unit, a second power supply unit and an initial power supply unit. In an exemplary embodiment, the OLED display substrate at least includes a plurality of scan signal lines (S1 to SN), a plurality of data signal lines (D1 to DM) and a plurality of emitting signal lines (EM1 to EMN); the scan signal driver is configured to sequentially supply scan signals to the plurality of scan signal lines (S1 to SN), the data signal driver is configured to supply data signals to the plurality of data signal lines (D1 to DM), and the light emitting signal driver is configured to sequentially supply emitting control signals to the plurality of emitting signal lines (EM1 to EMN). In an exemplary embodiment, the plurality of scan signal lines and the plurality of emitting signal lines extend along a horizontal direction, and the plurality of data signal lines extend along a vertical direction. The display apparatus includes a plurality of sub-pixels, and one sub-pixel is connected with a scan signal line, a light emitting control line and a data signal line, for example. The first power supply unit, the second power supply unit, and the initial power supply unit are configured to provide a first power supply voltage, a second power supply voltage, and an initial power supply voltage to a pixel circuit through a first power supply line, a second power supply line, and an initial signal line respectively.

FIG. 2 is a schematic diagram of a planar structure of a display area of a display substrate. As shown in FIG. 2, a display area may include a plurality of pixel units P arranged in a matrix, at least one of the plurality of pixel units P includes a first sub-pixel P1 emitting light of a first color, a second sub-pixel P2 emitting light of a second color, and a third sub-pixel P3 emitting light of a third color. The first sub-pixel P1, the second sub-pixel P2, and the third sub-pixel P3 each include a pixel drive circuit and a light emitting device. Pixel drive circuits in the first sub-pixel P1, the second sub-pixel P2, and the third sub-pixel P3 are connected with a scan signal line, a data signal line, and a light emitting signal line respectively. The pixel drive circuit is configured to receive a data voltage transmitted by the data signal line under control of the scan signal line and the light emitting signal line, and output a corresponding current to the light emitting device. Light emitting devices in the first sub-pixel P1, the second sub-pixel P2, and the third sub-pixel P3 are respectively connected with a pixel drive circuit of a sub-pixel where a light emitting device is located, and the light emitting device is configured to emit light with corresponding brightness in response to a current output by the pixel drive circuit of the sub-pixel where the light emitting device is located.

In an exemplary embodiment, the pixel unit P may include a red (R) sub-pixel, a green (G) sub-pixel and a blue (B) sub-pixel, or may include a red sub-pixel, a green sub-pixel, a blue sub-pixel and a white (W) sub-pixel, which is not limited in the present disclosure. In an exemplary embodiment, a shape of a sub-pixel in a pixel unit may be a rectangle, a rhombus, a pentagon, or a hexagon. When the pixel unit includes three sub-pixels, the three sub-pixels may be disposed side by side horizontally, side by side vertically, or in the form of “do”; and when the pixel unit includes four sub-pixels, the four sub-pixels may be disposed side by side horizontally, side by side vertically, or in the shape of a square, which is not limited in the present disclosure.

FIG. 3 is a schematic diagram of a sectional structure of a display substrate, which illustrates a structure of three sub-pixels of an OLED display substrate. As shown in FIG. 3, on a plane perpendicular to the display substrate, the display substrate may include a drive circuit layer 102 disposed on a base substrate 101, a light emitting device 103 disposed on a side of the drive circuit layer 102 away from the base substrate 101, and an encapsulation layer 104 disposed on a side of the light emitting device 103 away from the base substrate 101. In some possible embodiments, the display substrate may include another film layer, such as post spacer, which is not limited in the present disclosure.

In an exemplary embodiment, the base substrate may be a flexible base substrate or may be a rigid base substrate. The flexible base substrate may include a first flexible material layer, a first inorganic material layer, a semiconductor layer, a second flexible material layer, and a second inorganic material layer which are stacked, wherein materials of the first flexible material layer and the second flexible material layer may be polyimide (PI), polyethylene terephthalate (PET), or a surface-treated polymer soft film, or the like, materials of the first inorganic material layer and the second inorganic material layer may be silicon nitride (SiNx) or silicon oxide (SiOx), or the like, for improving a water and oxygen resistance capability of the base substrate, and a material of the semiconductor layer may be amorphous silicon (a-si).

In an exemplary embodiment, the drive circuit layer 102 of each sub-pixel may include a plurality of transistors and a storage capacitor constituting a pixel drive circuit. FIG. 3 illustrates an example in which each sub-pixel includes one drive transistor and one storage capacitor. In some possible implementations, the drive circuit layer 102 of each sub-pixel may include a first insulation layer 201 disposed on the base substrate; an active layer disposed on the first insulation layer; a second insulation layer 202 covering the active layer; a gate electrode and a first capacitor electrode disposed on the second insulation layer 202; a third insulation layer 203 covering the gate electrode and the first capacitor electrode; a second capacitor electrode disposed on the third insulation layer 203; a fourth insulation layer 204 covering the second capacitor electrode, the second insulation layer 202, the third insulation layer 203 and the fourth insulation layer 204 being provided with vias exposing the active layer; a source electrode and a drain electrode disposed on the fourth insulation layer 204, the source electrode and the drain electrode being respectively connected with the active layer through vias; a planarization layer 205 covering the structure and provided with vias exposing the drain electrode. The active layer, the gate electrode, the source electrode, and the drain electrode form the drive transistor 210, and the first capacitance electrode and the second capacitance electrode form the storage capacitor 211.

In an exemplary embodiment, the light emitting device 103 may include an anode 301, a pixel definition layer 302, an organic light emitting layer 303 and a cathode 304. The anode 301 is disposed on the planarization layer 205, and is connected to the drain electrode of the drive transistor 210 through a via hole provided on the planarization layer 205; the pixel definition layer 302 is disposed on the anode 301 and the planarization layer 205, and the pixel definition layer 302 is provided with a pixel opening exposing the anode 301; the organic light emitting layer 303 is at least partially disposed in the pixel opening, and is connected to the anode 301; the cathode 304 is disposed on the organic light emitting layer 303, and is connected to the organic light emitting layer 303; and the organic light emitting layer 303 emits light of corresponding colors under the drive of the anode 301 and the cathode 304.

In an exemplary embodiment, the encapsulation layer 104 may include a first encapsulation layer 401, a second encapsulation layer 402 and a third encapsulation layer 403 that are stacked; the first encapsulation layer 401 and the third encapsulation layer 403 may be made of an inorganic material, and the second encapsulation layer 402 may be made of an organic material; and the second encapsulation layer 402 is disposed between the first encapsulation layer 401 and the third encapsulation layer 403 to ensure that external vapor may not enter into the light emitting device 103.

In an exemplary embodiment, the organic light emitting layer 303 may at least include a hole injection layer 11, a hole transport layer 20, a light emitting layer 40 and a hole block layer 50 which are stacked on the anode 301.

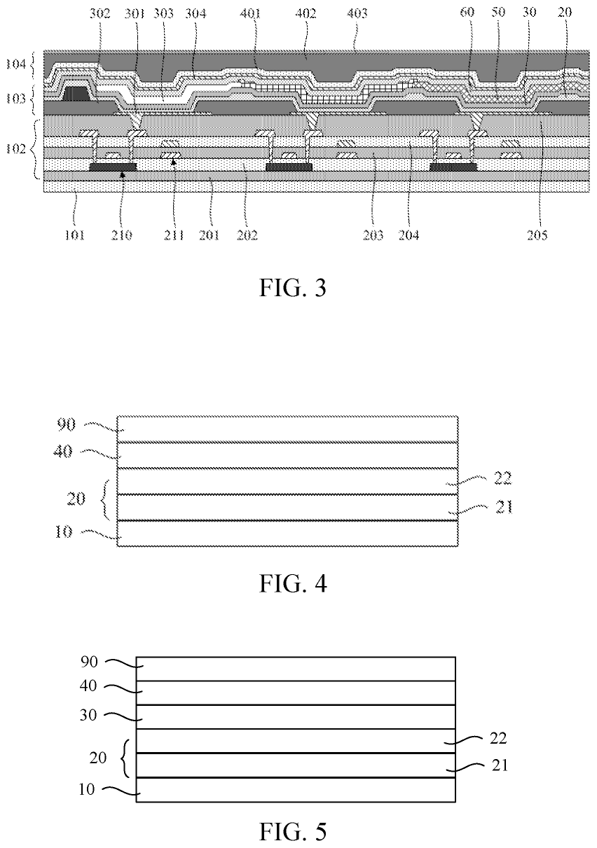

FIG. 4 is a schematic diagram of structure of an exemplary organic light emitting device according to an example of the present disclosure. The organic light emitting device includes an anode 10, a cathode 90, and a first hole transport layer 20 and a first light emitting layer 40 arranged between the anode and the cathode, wherein the first hole transport layer 20 is located between the first light emitting layer 40 and the anode 10; the first hole transport layer 20 at least includes a first hole sublayer 21 and a second hole sublayer 22; a material of the first hole sublayer 21 includes a first material and a second material, and a material of the second hole sublayer 22 includes at least one of the first material and the second material; and
wherein the first material includes, but is not limited to, a compound having a structure of Formula 1:

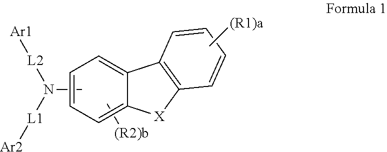

in Formula 1:
X is O, S, C, or N;
L1 and L2 are each independently a direct bond, each independently a substituted or unsubstituted C6-C60 aryl;
Ar1 and Ar2 are each independently hydrogen, deuterium, a halogen group, nitrile, nitro, hydroxyl, carbonyl, an ester group, imide, amino, a substituted or unsubstituted silyl, a substituted or unsubstituted boron, a substituted or unsubstituted alkyl, a substituted or unsubstituted cycloalkyl, a substituted or unsubstituted alkoxy, a substituted or unsubstituted aryloxy, a substituted or unsubstituted alkylthio, a substituted or unsubstituted arylthio, a substituted or unsubstituted alkylsulfonyl, a substituted or unsubstituted arylsulfonyl, a substituted or unsubstituted alkenyl, a substituted or unsubstituted arylalkyl, a substituted or unsubstituted arylalkenyl, a substituted or unsubstituted alkylaryl, a substituted or unsubstituted alkylamine, a substituted or unsubstituted arylalkylamine, a substituted or unsubstituted heteroarylamine, a substituted or unsubstituted arylamine, a substituted or unsubstituted arylheteroarylamine, a substituted or unsubstituted arylphosphine, a substituted or unsubstituted phosphine oxide group, a substituted or unsubstituted aryl, or a substituted or unsubstituted heterocyclic group; or represented by Formula 2 below:

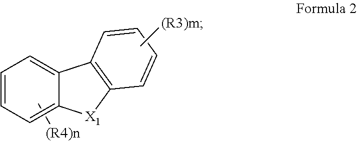

R1, R2, R3 and R4 are each independently selected from deuterium, a halogen group, cyano, C3-C20 heteroaryl, C6-C20 aryl, C3-C12 trialkylsilyl, C18-C30 triarylsilyl, C1-C5 alkyl, C1-C10 haloalkyl, C3-C10 cycloalkyl, C2-C10 heterocycloalkyl, C5-C10 cycloalkenyl, C4-C10 heterocycloalkenyl, C1-C10 alkoxy, C1-C10 alkylthio, C6-C18 aryloxy, C6-C18 arylthio, C6-C24 phosphoroxy, C6-C18 alkylsulfonyl, C3-C18 trialkylphosphine, C3-C18 trialkylboron; or optionally bonded to adjacent groups to form a ring;
a, b, m and n are each independently an integer of 0-4.

The first hole sublayer 21 is located between the second hole sublayer 22 and the anode 10. A difference between a LUMO (Lowest Unoccupied Molecular Orbit) energy level of the first material and a HOMO (Highest Occupied Molecular Orbit) energy level of the second material is between −0.3 eV and 1.0 eV.

FIG. 5 is a schematic diagram of structure of another exemplary organic light emitting device according to an example of the present disclosure. The organic light emitting device includes an anode 10, a cathode 90, and a first hole transport layer 20 and a first light emitting layer 40 arranged between the anode and the cathode, wherein the first hole transport layer 20 is located between the first light emitting layer 40 and the anode 10; the first hole transport layer 20 at least includes a first hole sublayer 21 and a second hole sublayer 22; a material of the first hole sublayer 21 includes a first material and a second material, and a material of the second hole sublayer 22 includes at least one of the first material and the second material; and the organic light emitting device further includes a first electron block layer 30 located between the first light emitting layer 40 and the first hole transport layer 20, and a difference between a HOMO energy level of a material of the second hole sublayer and a LUMO energy level of the first electron block layer is less than or equal to 0.4 eV. A difference between the LUMO energy level of the first electron block layer and a HOMO energy level of the first light emitting layer is less than or equal to 0.4 eV. A mobility of a material of the second hole sublayer is greater than a mobility of the first electron block layer.

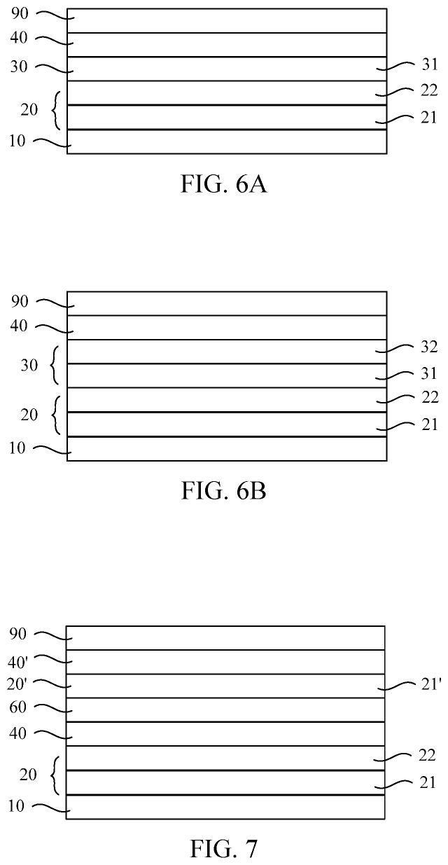

FIG. 6A and FIG. 6B are schematic diagrams of structure of further exemplary organic light emitting devices according to an example of the present disclosure. In FIG. 6A, the organic light emitting device includes an anode 10, a cathode 90, and a first hole transport layer 20 and a first light emitting layer 40 arranged between the anode and the cathode, wherein the first hole transport layer 20 is located between the first light emitting layer 40 and the anode 10; the first hole transport layer 20 at least includes a first hole sublayer 21 and a second hole sublayer 22; a material of the first hole sublayer 21 includes a first material and a second material, and a material of the second hole sublayer 22 includes at least one of the first material and the second material; and the organic light emitting device further includes a first electron block layer 30 located between the first light emitting layer 40 and the first hole transport layer 20, and a difference between a HOMO energy level of a material of the second hole sublayer and a LUMO energy level of the first electron block layer is less than or equal to 0.4 eV; a difference between the LUMO energy level of the first electron block layer and a HOMO energy level of the first light emitting layer is less than or equal to 0.4 eV; and the first electron block layer 30 includes a first block sublayer 31. In FIG. 6B, the organic light emitting device includes an anode 10, a cathode 90, and a first hole transport layer 20 and a first light emitting layer 40 arranged between the anode and the cathode, wherein the first hole transport layer 20 is located between the first light emitting layer 40 and the anode 10; the first hole transport layer 20 at least includes a first hole sublayer 21 and a second hole sublayer 22; a material of the first hole sublayer 21 includes a first material and a second material, and a material of the second hole sublayer 22 includes at least one of the first material and the second material; and the organic light emitting device further includes a first electron block layer 30 located between the first light emitting layer 40 and the first hole transport layer 20, and a difference between a HOMO energy level of a material of the second hole sublayer and a LUMO energy level of the first electron block layer is less than or equal to 0.4 eV; a difference between the LUMO energy level of the first electron block layer and a HOMO energy level of the first light emitting layer is less than or equal to 0.4 eV; and the first electron block layer 30 includes a first block sublayer 31 and a second block sublayer 32, the second block sublayer is located between the first block sublayer and the first light emitting layer, and a material of the first block sublayer is different from a material of the second block sublayer.

In an exemplary embodiment of the present disclosure, a resistivity of the first hole sublayer 21 is greater than or equal to 100 Ω·m.

FIG. 7 is a schematic diagram of structure of a further exemplary organic light emitting device according to an example of the present disclosure. The organic light emitting device further includes a charge generation layer 60, a second hole transport layer 20′ and a second light emitting layer 40′, the charge generation layer 60 is located on a side of the first light emitting layer 40 close to the cathode, the second hole transport layer 20′ is located on a side of the charge generation layer close to the cathode, and the second light emitting layer 40′ is located between the second hole transport layer 20′ and the cathode; and the second hole transport layer 20′ includes at least a third hole sublayer 21′, and a material of the third hole sublayer 21′ includes the first material and the second material; the third hole sublayer 21′ is located between the second light emitting layer 40′ and the charge generation layer 60; a mobility M₂ of the material of the second hole sublayer 22 and a mobility M₄ of the material of the third hole sublayer 21′ meet the following condition:

10⁻¹ cm²/Vs≤M₂/M₄≤10 cm²/Vs; and
the organic light emitting device further includes a second electron block layer 30′, the second electron block layer 30′ is located between the second light emitting layer 40′ and the second hole transport layer 20′, and a difference between a HOMO energy level of the material of the third hole sublayer 21′ and a LUMO energy level of the second electron block layer 30′ is less than or equal to 0.4 eV; a mobility of the material of the third hole sublayer 21′ is greater than a mobility of the second electron block layer 30′; and a difference between a LUMO energy level of the fourth block sublayer 32′ and a HOMO energy level of the second light emitting layer is less than or equal to 0.4 eV.

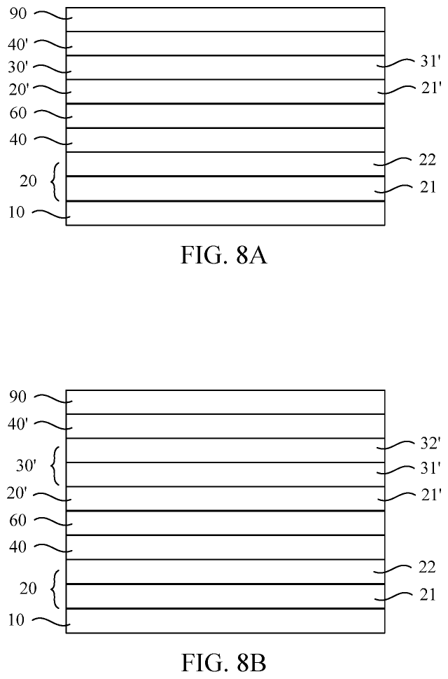

FIG. 8A and FIG. 8B are schematic diagrams of structure of further exemplary organic light emitting devices according to an example of the present disclosure. In FIG. 8A, the organic light emitting device further includes a second electron block layer 30′, the second electron block layer 30′ includes a third block sublayer 31′. In FIG. 8B, the organic light emitting device further includes a second electron block layer 30′, the second electron block layer 30′ includes a third block sublayer 31′ and a fourth block sublayer 32′, the fourth block sublayer 32′ is located between the third block sublayer 31′ and the second light emitting layer 40′, and a material of the third block sublayer 31′ is different from a material of the fourth block sublayer 32′.

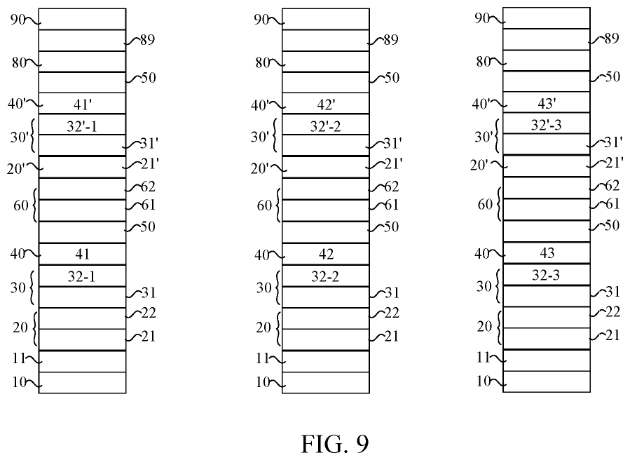

FIG. 9 is a schematic diagram of structure of a further exemplary organic light emitting device according to an example of the present disclosure, including an anode 10, a cathode 90, and a first hole transport layer 20 and a first light emitting layer 40 arranged between the anode and the cathode, wherein the first hole transport layer 20 is located between the first light emitting layer 40 and the anode 10; the first hole transport layer 20 at least includes a first hole sublayer 21 and a second hole sublayer 22; a material of the first hole sublayer 21 includes a first material and a second material, and a material of the second hole sublayer 22 includes at least one of the first material and the second material; and the organic light emitting device further includes a first electron block layer 30 located between the first light emitting layer 40 and the first hole transport layer 20, and a difference between a HOMO energy level of a material of the second hole sublayer and a LUMO energy level of the first electron block layer is less than or equal to 0.4 eV; a difference between the LUMO energy level of the first electron block layer and a HOMO energy level of the first light emitting layer is less than or equal to 0.4 eV; and the first electron block layer 30 includes a first block sublayer 31 and a second block sublayer 32; (wherein 41 is a light emitting layer 1 which can emit red light; 42 is a light emitting layer 2, which can emit green light; 43 is a light emitting layer 3 which can emit blue light; and each light emitting layer is provided with a corresponding electron block sublayer 32-1, 32-2 or 32-3); the organic light emitting device further includes a charge generation layer 60 (61 is an N-type charge generation layer and 62 is a P-type charge generation layer), a second hole transport layer 20′ and a second light emitting layer 40′, the charge generation layer 60 is located on a side of the first light emitting layer 40 close to the cathode, the second hole transport layer 20′ is located on a side of the charge generation layer close to the cathode, and the second light emitting layer 40′ is located between the second hole transport layer 20′ and the cathode; and the second hole transport layer 20′ includes at least a third hole sublayer 21′, and a material of the third hole sublayer 21′ includes the first material and the second material; the third hole sublayer 21′ is located between the second light emitting layer 40′ and the charge generation layer 60; a mobility M₂ of the material of the second hole sublayer 22 and a mobility M₄ of the material of the third hole sublayer 21′ meet the following condition:

10⁻¹ cm²/Vs≤M₂/M₄≤10 cm²/Vs; and
the organic light emitting device further includes a second electron block layer 30′, the second electron block layer 30′ is located between the second light emitting layer 40′ and the second hole transport layer 20′, and a difference between a HOMO energy level of the material of the third hole sublayer 21′ and a LUMO energy level of the second electron block layer 30′ is less than or equal to 0.4 eV; a mobility of the material of the third hole sublayer 21′ is greater than a mobility of the second electron block layer 30′; and a difference between a LUMO energy level of the fourth block sublayer 32′ and a HOMO energy level of the second light emitting layer is less than or equal to 0.4 eV. The organic light emitting device further includes a second electron block layer 30′, the second electron block layer 30′ includes a third block sublayer 31′ and a fourth block sublayer 32′, the fourth block sublayer 32′ is located between the third block sublayer 31′ and the second light emitting layer 40′, and a material of the third block sublayer 31′ is different from a material of the fourth block sublayer 32′ (wherein 41′ is a light emitting layer 1 which can emit red light; 42′ is a light emitting layer 2, which can emit green light; 43′ is a light emitting layer 3 which can emit blue light; and each light emitting layer is provided with a corresponding electron block sublayer 32′-1, 32′-2 or 32′-3).

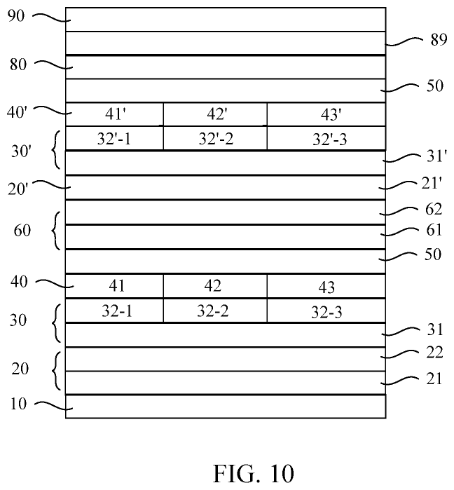

FIG. 10 is a schematic diagram of structure of a further exemplary organic light emitting device according to an example of the present disclosure, including an anode 10, a cathode 90, and a first hole transport layer 20 and a first light emitting layer 40 arranged between the anode and the cathode, wherein the first hole transport layer 20 is located between the first light emitting layer 40 and the anode 10; the first hole transport layer 20 at least includes a first hole sublayer 21 and a second hole sublayer 22; a material of the first hole sublayer 21 includes a first material and a second material, and a material of the second hole sublayer 22 includes at least one of the first material and the second material; and the organic light emitting device further includes a first electron block layer 30 located between the first light emitting layer 40 and the first hole transport layer 20, and a difference between a HOMO energy level of a material of the second hole sublayer and a LUMO energy level of the first electron block layer is less than or equal to 0.4 eV; a difference between the LUMO energy level of the first electron block layer and a HOMO energy level of the first light emitting layer is less than or equal to 0.4 eV; and the first electron block layer 30 includes a first block sublayer 31 and a second block sublayer 32; (wherein 41 is a light emitting layer 1 which can emit red light, green light or blue light; 42 is a light emitting layer 2, which can emit red light, green light or blue light; 43 is a light emitting layer 3 which can emit red light, green light or blue light; and each light emitting layer is provided with a corresponding electron block sublayer 32-1, 32-2 or 32-3); the organic light emitting device further includes a charge generation layer 60 (61 is an N-type charge generation layer and 62 is a P-type charge generation layer), a second hole transport layer 20′ and a second light emitting layer 40′, the charge generation layer 60 is located on a side of the first light emitting layer 40 close to the cathode, the second hole transport layer 20′ is located on a side of the charge generation layer close to the cathode, and the second light emitting layer 40′ is located between the second hole transport layer 20′ and the cathode; and the second hole transport layer 20′ includes at least a third hole sublayer 21′, and a material of the third hole sublayer 21′ includes the first material and the second material; the third hole sublayer 21′ is located between the second light emitting layer 40′ and the charge generation layer 60; a mobility M₂ of the material of the second hole sublayer 22 and a mobility M₄ of the material of the third hole sublayer 21′ meet the following condition:

10⁻¹ cm²/Vs≤M₂/M₄≤10 cm²/Vs; and
the organic light emitting device further includes a second electron block layer 30′, the second electron block layer 30′ is located between the second light emitting layer 40′ and the second hole transport layer 20′, and a difference between a HOMO energy level of the material of the third hole sublayer 21′ and a LUMO energy level of the second electron block layer 30′ is less than or equal to 0.4 eV; a mobility of the material of the third hole sublayer 21′ is greater than a mobility of the second electron block layer 30′; and a difference between a LUMO energy level of the fourth block sublayer 32′ and a HOMO energy level of the second light emitting layer is less than or equal to 0.4 eV. The organic light emitting device further includes a second electron block layer 30′, the second electron block layer 30′ includes a third block sublayer 31′ and a fourth block sublayer 32′, the fourth block sublayer 32′ is located between the third block sublayer 31′ and the second light emitting layer 40′, and a material of the third block sublayer 31′ is different from a material of the fourth block sublayer 32′ (wherein 41′ is a light emitting layer 1 which can emit red light, green light or blue light; 42′ is a light emitting layer 2, which can emit red light, green light or blue light; 43′ is a light emitting layer 3 which can emit red light, green light or blue light; and each light emitting layer is provided with a corresponding electron block sublayer 32′-1, 32′-2 or 32′-3).

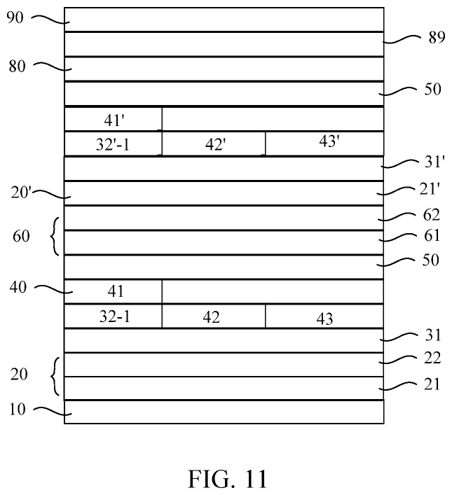

FIG. 11 is a schematic diagram of structure of a further exemplary organic light emitting device according to an example of the present disclosure. The main structure of the device in this figure is similar to that of the device in FIG. 10, except that 41 is a light emitting layer 1 which can emit red light, green light or blue light; 42 is a light emitting layer 2 which can emit red light, green light or blue light; 43 is a light emitting layer 3 which can emit red light, green light or blue light; and 41 is located above 42 and 43, and 41 is provided with a corresponding electron block sublayer 32-1; 41′ is a light emitting layer 1 which can emit red light, green light or blue light; 42′ is a light emitting layer 2 which can emit red light, green light or blue light; 43′ is a light emitting layer 3 which can emit red light, green light or blue light; and 41′ is located above 42′ and 43′, and 41′ is provided with a corresponding electron block sublayer 32′-1.

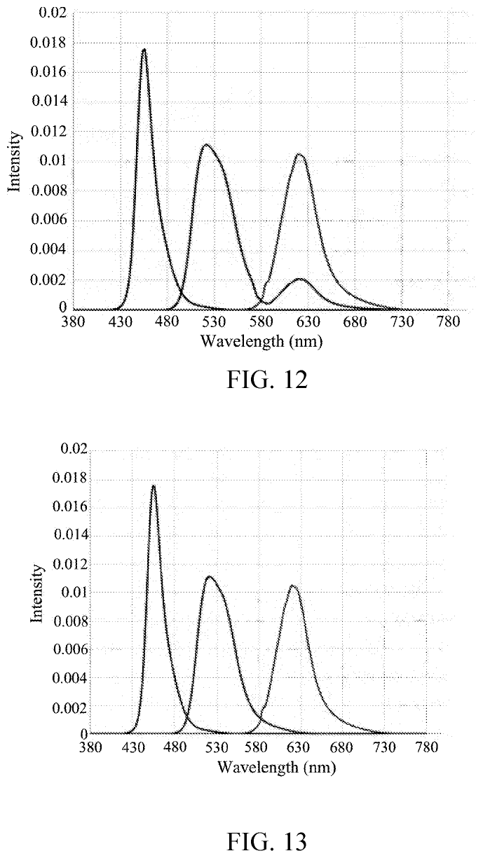

FIG. 12 is an exemplary crosstalk phenomenon, in which a longitudinal direction represents light intensity; a transverse direction represents wavelength, a wavelength range of blue light is 440 nm-475 nm, a wavelength range of green light is 492 nm-577 nm, and a wavelength range of red light is 622 nm-760 nm. As can be seen from the figure, when the light emitting layer works, electrons of green light at a middle wavelength flow transversely to a peak of red light at a right wavelength, and there is a relatively small peak.

FIG. 13 is an exemplary crosstalk-free spectrum of a device of the present disclosure, in which a longitudinal direction represents light intensity; a transverse direction represents wavelength, a wavelength range of blue light is 440 nm-475 nm, a wavelength range of green light is 492 nm-577 nm, and a wavelength range of red light is 622 nm-760 nm. As can be seen from the figure, the light emitting device of the present disclosure can effectively reduce crosstalk and improve the display effect.

In an exemplary embodiment, an organic light emitting layer of an OLED light emitting device may include an emitting layer (EML), and include one or more of a hole injection layer (HIL), a hole transport layer (HTL), a hole block layer (HBL), an electron block layer (EBL), an electron injection layer (EIL) and an electron transport layer (ETL). Under driving of voltages of an anode and a cathode, light is emitted according to a required gray scale using light emitting properties of organic materials.

In an OLED structure, a material used for a hole injection layer HIL may be selected from an inorganic oxide, such as a molybdenum oxide, a titanium oxide, a vanadium oxide, a rhenium oxide, a ruthenium oxide, a chromium oxide, a zirconium oxide, a hafnium oxide, a tantalum oxide, a silver oxide, a tungsten oxide, a manganese oxide etc.; and may also be selected from a dopant from a strong electron absorption system, such as F4TCNQ, HATCN, etc.

In another OLED structure, the charge generation layer includes a P-type charge generation layer (CGL) and an N-type CGL, the P-type CGL may be a hole-type material, such as NPB, TPD, etc., and the N-type charge generation layer may be a phenanthroline or phosphoroxy-containing electron material. Both the P-type CGL and the N-type CGL may contain a dopant, the dopant of the P-type charge generation layer may be HATCN, F4TCNQ, etc., and the dopant of the N-type charge generation layer may be an alkali metal such as lithium (Li), sodium (Na), potassium (K) or cesium (Cs) or an alkali metal or alkaline earth metal such as magnesium (Mg), strontium (Sr), barium (Ba) or radium (Ra) and an oxide thereof. As an N-type CGL, electrons may be injected into the first light emitting unit. As a P-type CGL, holes may be injected into the second light emitting unit.

In another OLED structure, the electron injection layer is generally an alkali metal or a metal, such as LiF, Yb, Mg, Ca or their compounds, etc.

In a further OLED structure, an indium tin oxide ITO layer on a glass underlay substrate serves as an anode, a hole injection layer (5-30 nm), a first hole sublayer (15-25 nm), a second hole sublayer (5-45 nm), a third hole sublayer (10-25 nm), a red light emitting layer (30-50 nm), a green light emitting layer (30-50 nm), a blue light emitting layer (10-20 nm), a first hole block layer (5-15 nm), an N-type charge generation layer (15-25 nm), a P-type charge generation layer (5-15 nm), a first hole sublayer (15-25 nm), a second hole sublayer (5-45 nm), a third hole sublayer GEBL (10-25 nm), a red light emitting layer (30-50 nm), a green light emitting layer (30-50 nm), a blue light emitting layer (10-20 nm), a second block sublayer (5-15 nm), an electron transport layer (20-100 nm), an electron injection layer (1-10 nm), and a cathode (10-20 nm).

In a still further OLED structure, a physical relationship of each layer of a stacked organic light emitting device is as follows:
(1) a first EML layer and a second EML layer each include three RGB light emitting layers, and a wavelength difference between upper and lower layers with a same color is less than or equal to 20 nm, so as to ensure that there is no obvious aberration aberration between two light emitting layers;
when two light emitting units include only one light emitting layer, the light emitting layer can emit one of red light, green light and blue light; and when they include three light emitting layers, they can emit red light, blue light and green light;
(2) a difference between a LUMO energy level of a first material and a HOMO energy level of a second material is between-0.3 eV and 1.0 eV;
a difference between a HOMO energy level of a material of a second hole sublayer and a LUMO energy level of a first electron block layer is less than or equal to 0.4 eV to ensure smooth carrier transmission;
a difference between the LUMO energy level of the first electron block layer and a HOMO energy level of a first light emitting layer is less than or equal to 0.4 eV to ensure that holes are well injected into the light emitting layer;
(3) a mobility of a material of a second hole sublayer is greater than a mobility of the first electron block layer, and the second hole sublayer has a greater mobility in a thickness direction of the electron block layer, which can prevent the voltage from being relatively high, thereby ensuring the voltage and performance of the device;
a mobility M₂ of the material of the second hole sublayer (HTL-1) in the first light emitting unit and a mobility M₄ of the material of the third hole sublayer (HTL-2) in the second light emitting unit meet the following condition:
10⁻¹ cm²/Vs≤M₂/M₄≤10 cm²/Vs, so that there is no obvious difference between the composite areas of the two EML layers;
(4) resistivity of hole injection layer: ≥100 Ω·m, a transverse current of the hole transport layer solves the problem of color crosstalk between the light emitting units.

TABLE 1
Commercial materials commonly used in each functional layer

| | |
|---|---|
| HIL | 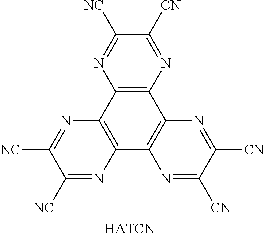 |
| | 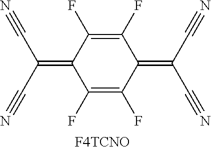 |
| | 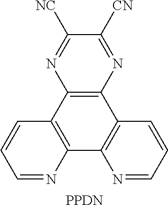 |
| HTL | 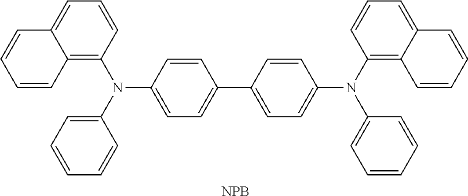 [SMILES: c1ccc(N(c2ccc(-c3ccc(N(c4ccccc4)c4cccc5ccccc45)cc3)cc2)c2cccc3ccccc23)cc1 ; "NPB"] |
| | 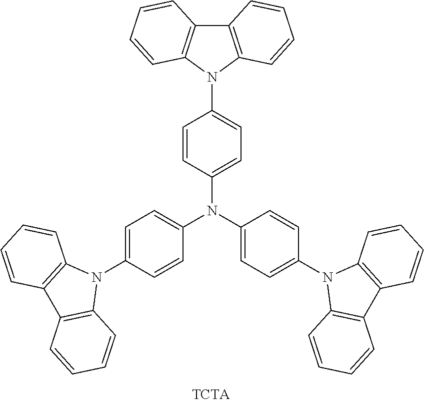 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1] |
| | 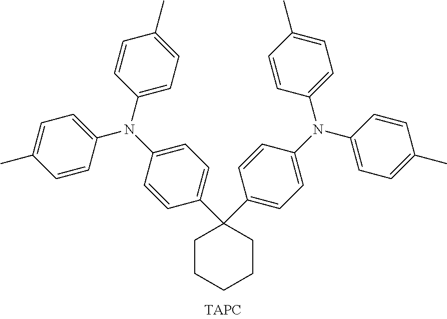 |
| ETL | 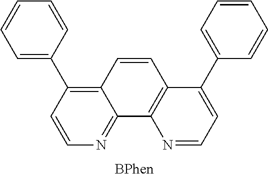 [SMILES: c1ccc(-c2ccnc3c2ccc2c(-c4ccccc4)ccnc23)cc1] |
| | 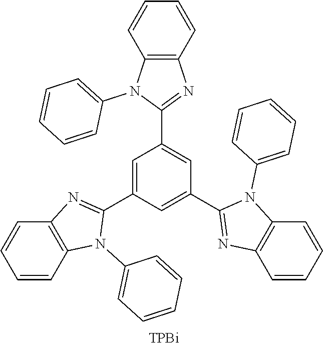 |
| Host material | 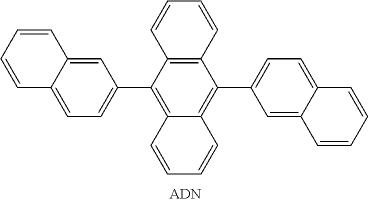 [SMILES: c1ccc2cc(-c3c4ccccc4c(-c4ccc5ccccc5c4)c4ccccc34)ccc2c1] |
| | BH |
| | 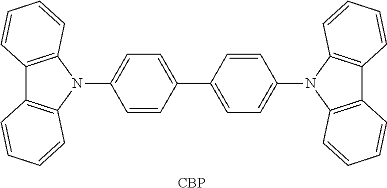 [SMILES: c1ccc2c(c1)c1ccccc1n2-c1ccc(-c2ccc(-n3c4ccccc4c4ccccc43)cc2)cc1 ; "CBP"] |
| | GH |
| | 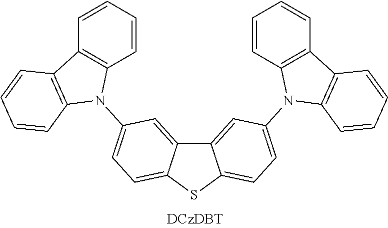 [SMILES: c1ccc2c(c1)c1ccccc1n2-c1ccc2sc3ccc(-n4c5ccccc5c5ccccc54)cc3c2c1] |
| | RH |
| Guest material | 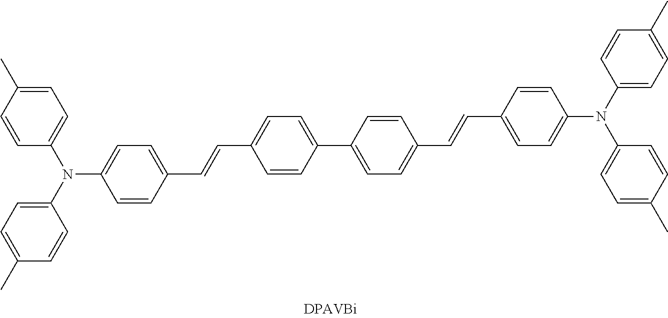 [SMILES: Cc1ccc(N(c2ccc(C)cc2)c2ccc(/C=C/c3ccc(-c4ccc(/C=C/c5ccc(N(c6ccc(C)cc6)c6ccc(C)cc6)cc5)cc4)cc3)cc2)cc1] |
| | BD |
| | 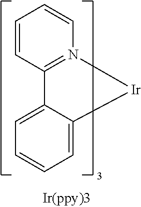 |
| | GD |
| | 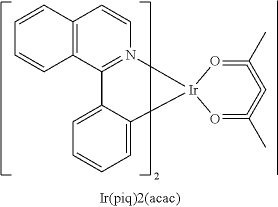 |
| | RD |
| P-CGL | 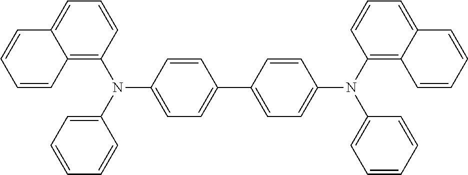 [SMILES: c1ccc(N(c2ccc(-c3ccc(N(c4ccccc4)c4cccc5ccccc45)cc3)cc2)c2cccc3ccccc23)cc1] |
| | 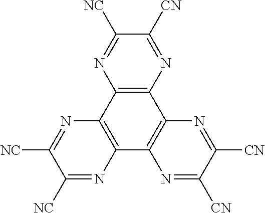 [SMILES: N#Cc1nc2c3nc(C#N)c(C#N)nc3c3nc(C#N)c(C#N)nc3c2nc1C#N] |
| N-CGL | 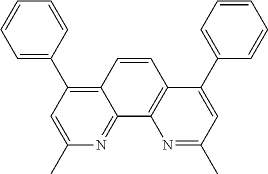 [SMILES: Cc1cc(-c2ccccc2)c2ccc3c(-c4ccccc4)cc(C)nc3c2n1] |
| | Li |
| | Yb |

N-CGL may be represented by Formula 5 below:

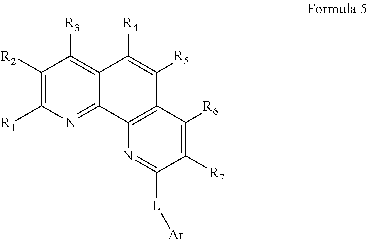

in Formula 5, R1 to R7 are the same or different, each independently selected from any of the following: hydrogen; deuterium; tritium; halogen; cyano; nitro; C6-C60 aryl; a C2-C60 heterocyclic group containing at least one heteroatom from O, N, S, Si and P; a fused ring group of C3-C60 aliphatic ring and C6-C60 aromatic ring; C1-C50 alkyl; C2-C20 alkenyl; C2-C20 alkynyl; C1-C30 alkoxy; C6-C30 aryloxy; C3-C60 alkylsilyl; C18-C60 arylsilyl; and C8-C60 alkylarylsilyl; and one or more of R1 to R6 are cyano;
Ar is each independently selected from any of the following: hydrogen; deuterium; tritium; halogen; cyano; nitro; C6-C60 aryl; a C2-C60 heterocyclic group containing at least one heteroatom from O, N, S, Si and P; a fused ring group of C3-C60 aliphatic ring and C6-C60 aromatic ring; C1-C50 alkyl; C2-C20 alkenyl; C2-C20 alkynyl; C1-C30 alkoxy; C6-C30 aryloxy; C3-C60 alkylsilyl; C18-C60 arylsilyl; and C8-C60 alkylarylsilyl;
L is selected from any of the following: C6-C60 arylene; a C2-C60 divalent heterocyclic group containing at least one heteroatom from O, N, S, Si and P; a divalent fused ring group of C3-C60 aliphatic ring and C6-C60 aromatic ring.

The compound of Formula 5 is selected from one or more of the following compounds:

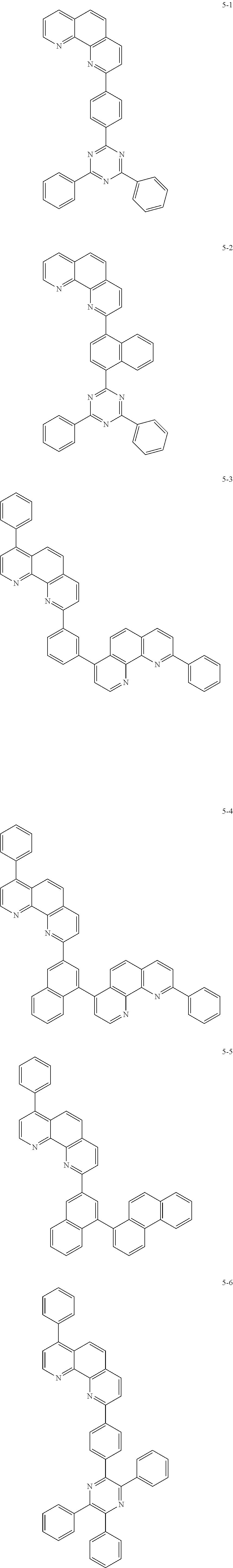 [SMILES: c1ccc(-c2nc(-c3ccccc3)nc(-c3ccc(-c4ccc5ccc6cccnc6c5n4)cc3)n2)cc1 ; c1ccc(-c2nc(-c3ccccc3)nc(-c3ccc(-c4ccc5ccc6cccnc6c5n4)c4ccccc34)n2)cc1 ; c1ccc(-c2ccc3ccc4c(-c5cccc(-c6ccc7ccc8c(-c9ccccc9)ccnc8c7n6)c5)ccnc4c3n2)cc1 ; c1ccc(-c2ccc3ccc4c(-c5cc(-c6ccc7ccc8c(-c9ccccc9)ccnc8c7n6)cc6ccccc56)ccnc4c3n2)cc1 ; c1ccc(-c2ccnc3c2ccc2ccc(-c4cc(-c5cccc6c5ccc5ccccc56)c5ccccc5c4)nc23)cc1 ; c1ccc(-c2nc(-c3ccccc3)c(-c3ccc(-c4ccc5ccc6c(-c7ccccc7)ccnc6c5n4)cc3)nc2-c2ccccc2)cc1]

### Resistivity Test

The structure used in the resistivity test in the table below is: transverse resistive substrate/P-type doped hole injection layer/hole transport layer, and thin film resistivity can reflect resistivity of the compound.

TABLE 2
Comparison of properties of various compounds

| | Recombination | Mobility | | | Resistivity |
|---|---|---|---|---|---|
| Compound | energy (eV) | m/(V · s) | HOMO (eV) | LUMO (eV) | (Ω · m) |
| Comparative | 0.25 | 5.96 × 10⁻⁵ | 5.32 | 2.36 | 77.4 |
| HTL | | | | | |
| Comparative | 0.26 | 2.11 × 10⁻⁵ | 5.39 | 2.35 | 88.5 |
| EBL | | | | | |
| 1-1 | 0.19 | 8.92 × 10⁻⁴ | 5.36 | 2.34 | 158.8 |
| 1-2 | 0.20 | 6.53 × 10⁻⁴ | 5.42 | 2.41 | 167.3 |
| 4-1 | 0.22 | 7.13 × 10⁻⁵ | 5.62 | 2.6 | 100.7 |
| 4-2 | 10.24 | 4.56 × 10⁻⁵ | 5.55 | 2.51 | 102.4 |

As can be seen from the results in the table, the compound of Formula 1 in the present invention has electron-rich units, allows effective adjustment of intramolecular conjugation length by links between groups, and has lower recombination energy and high hole mobility; and has relatively suitable HOMO energy level, enabling better transmission of holes. The specific links between groups enable the molecules of this kind to have a three-dimensional space structure, and the deposited thin film has greater transverse resistance. Color crosstalk is mainly caused by transverse leakage of the hole injection layer. The compound of Formula 1, as a hole transport material, has large transverse resistance after P-type doping, and therefore can effectively solve transverse diffusion of charges between different colors of light, greatly weaken color crosstalk and improve the display effect.

The compound of Formula 3 has a higher HOMO energy level than the comparative compounds and a higher HOMO energy level than the compound of Formula 2, and can well reduce the potential barrier between the hole transport layer and the light emitting layer, which is beneficial to carrier transport. At the same time, it has larger transverse resistance than the comparative compounds, which can further improve color crosstalk.

### Materials of Functional Layers Used in Examples

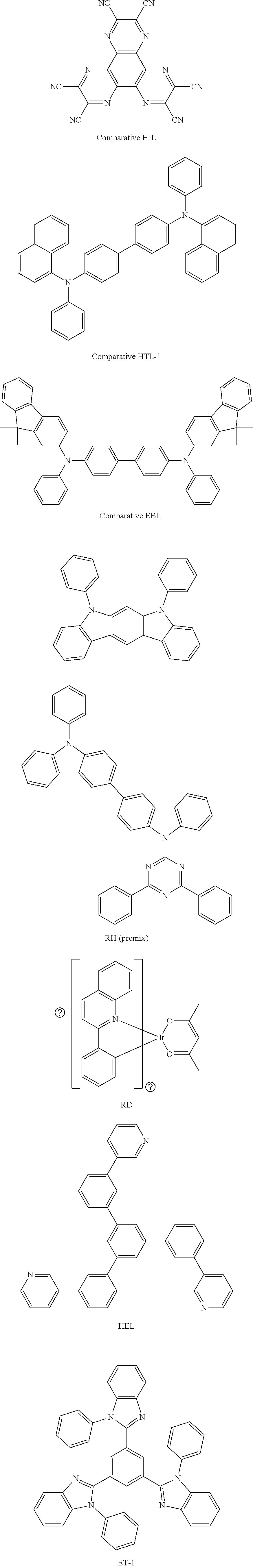

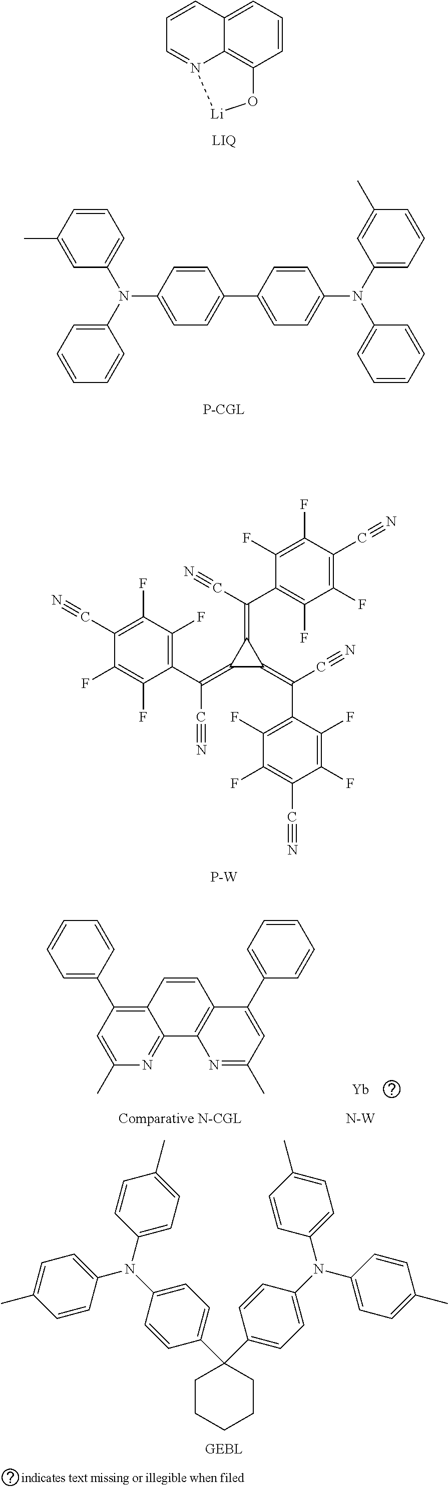

TABLE 3
EL devices prepared in the present disclosure

| Serial | First hole transport | Second hole | | |
|---|---|---|---|---|
| number | layer | transport layer | EBL | NCGL |
| Example 1 | 1-2 and 3-6 | 3-6 | 4-2 | 5-1 |
| Example 2 | 1-3 and 3-6 | 3-6 | 4-1 | 5-1 |
| Example 3 | 1-2 and 3-6 | Comparative | 4-2 | 5-1 |
| | | REBL | | |
| Example 4 | 1-2 and 3-6 | 3-6 | 4-2 | Comparative |
| | | | | NCGL |
| Example 5 | 1-2 and 3-6 | Comparative HTL | 4-2 | Comparative |
| | | | | NCGL |
| Example 6 | Comparative HIL and | 3-6 | 4-2 | 5-1 |
| | Comparative HTL | | | |
| Comparative | Comparative HIL and | Comparative HTL | Comparative | Comparative |
| example 1 | Comparative HTL | | EBL | NCGL |

TABLE 4
Parameters of EL devices in Table 3 above

| Serial | | | | EL | | |
|---|---|---|---|---|---|---|
| number | Voltage | Efficiency | Lifetime | spectrum | CIEx | CIEy |
| Example 1 | 94.89% | 115.06% | 115.02% | 625 | 0.685 | 0.315 |
| Example 2 | 95.63% | 110.77% | 111.62% | 625 | 0.684 | 0.315 |
| Example 3 | 96.06% | 106.85% | 106.14% | 625 | 0.685 | 0.316 |
| Example 4 | 96.29% | 104.72% | 105.51% | 626 | 0.685 | 0.316 |
| Example 5 | 99.08% | 103.21% | 102.78% | 626 | 0.686 | 0.315 |
| Example 6 | 99.83% | 102.06% | 101.87% | 624 | 0.683 | 0.317 |
| Comparative | 100% | 100% | 100% | 626 | 0.685 | 0.315 |
| Example 1 | | | | | | |

Although the embodiments disclosed in the present disclosure are as above, the described contents are only embodiments used for convenience of understanding the present disclosure and are not intended to limit the present disclosure. Any skilled person in the art to which the present disclosure pertains may make any modifications and alterations in forms and details of implementation without departing from the spirit and scope of the present disclosure. However, the scope of patent protection of the present application should still be subject to the scope defined by the appended claims.

1. An organic light emitting device, comprising an anode, a cathode, and a first hole transport layer and a first light emitting layer arranged between the anode and the cathode, wherein the first hole transport layer is located between the first light emitting layer and the anode; the first hole transport layer at least comprises a first hole sublayer and a second hole sublayer; and a material of the first hole sublayer comprises a first material and a second material, and a material of the second hole sublayer comprises at least one of the first material and the second material;
wherein the first material comprises, but is not limited to, a compound having a structure of Formula 1: 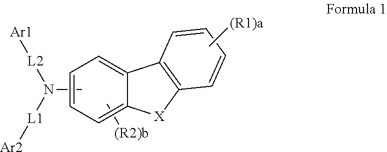
in Formula 1:
X is O, S, C, or N;
L1 and L2 are each independently a direct bond, each independently a substituted or unsubstituted C6-C60 aryl;
Ar1 and Ar2 are each independently hydrogen, deuterium, a halogen group, nitrile, nitro, hydroxyl, carbonyl, an ester group, imide, amino, a substituted or unsubstituted silyl, a substituted or unsubstituted boron, a substituted or unsubstituted alkyl, a substituted or unsubstituted cycloalkyl, a substituted or unsubstituted alkoxy, a substituted or unsubstituted aryloxy, a substituted or unsubstituted alkylthio, a substituted or unsubstituted arylthio, a substituted or unsubstituted alkylsulfonyl, a substituted or unsubstituted arylsulfonyl, a substituted or unsubstituted alkenyl, a substituted or unsubstituted arylalkyl, a substituted or unsubstituted arylalkenyl, a substituted or unsubstituted alkylaryl, a substituted or unsubstituted alkylamine, a substituted or unsubstituted arylalkylamine, a substituted or unsubstituted heteroarylamine, a substituted or unsubstituted arylamine, a substituted or unsubstituted arylheteroarylamine, a substituted or unsubstituted arylphosphine, a substituted or unsubstituted phosphine oxide group, a substituted or unsubstituted aryl, or a substituted or unsubstituted heterocyclic group; or represented by Formula 2 below: 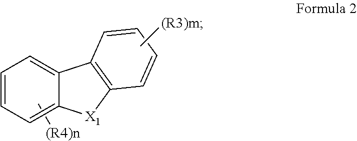
R1, R2, R3 and R4 are each independently selected from deuterium, a halogen group, cyano, C3-C20 heteroaryl, C6-C20 aryl, C3-C12 trialkylsilyl, C18-C30 triarylsilyl, C1-C5 alkyl, C1-C10 haloalkyl, C3-C10 cycloalkyl, C2-C10 heterocycloalkyl, C5-C10 cycloalkenyl, C4-C10 heterocycloalkenyl, C1-C10 alkoxy, C1-C10 alkylthio, C6-C18 aryloxy, C6-C18 arylthio, C6-C24 phosphoroxy, C6-C18 alkylsulfonyl, C3-C18 trialkylphosphine, C3-C18 trialkylboron; or optionally bonded to adjacent groups to form a ring; and
a, b, m and n are each independently an integer of 0-4.

2. The organic light emitting device according to claim 1, wherein the first hole sublayer is located between the second hole sublayer and the anode.

3. The organic light emitting device according to claim 1, wherein a difference between a LUMO energy level of the first material and a HOMO energy level of the second material is between −0.3 eV and 1.0 eV.

4. The organic light emitting device according to claim 1, wherein the organic light emitting device further comprises a first electron block layer located between the first light emitting layer and the first hole transport layer, and a difference between a HOMO energy level of a material of the second hole sublayer and a LUMO energy level of the first electron block layer is less than or equal to 0.4 eV.

5. The organic light emitting device according to claim 4, wherein a mobility of a material of the second hole sublayer is greater than a mobility of the first electron block layer.

6. The organic light emitting device according to claim 4, wherein a difference between the LUMO energy level of the first electron block layer and a HOMO energy level of the first light emitting layer is less than or equal to 0.4 eV.

7. The organic light emitting device according to claim 4, wherein
the first electron block layer comprises a first block sublayer, or
the first electron block layer comprises a first block sublayer and a second block sublayer, the second block sublayer is located between the first block sublayer and the first light emitting layer, and a material of the first block sublayer is different from a material of the second block sublayer.

8. The organic light emitting device according to claim 1, wherein a resistivity of the first hole sublayer is greater than or equal to 100 Ω·m.

9. The organic light emitting device according to claim 1, wherein
the organic light emitting device further comprises a charge generation layer, a second hole transport layer and a second light emitting layer, the charge generation layer is located on a side of the first light emitting layer close to the cathode, the second hole transport layer is located on a side of the charge generation layer close to the cathode, and the second light emitting layer is located between the second hole transport layer and the cathode; and
the second hole transport layer comprises at least a third hole sublayer, and a material of the third hole sublayer comprises the first material and the second material.

10. The organic light emitting device according to claim 9, wherein the third hole sublayer is located between the second light emitting layer and the charge generation layer.

11. The organic light emitting device according to claim 9, wherein a mobility M₂ of the material of the second hole sublayer and a mobility M₄ of the material of the third hole sublayer meet the following condition:
10⁻¹ cm²/Vs≤M₂/M₄≤10 cm²/Vs.

12. The organic light emitting device according to claim 9, wherein
the organic light emitting device further comprises a second electron block layer,
the second electron block layer comprises a third block sublayer, or the second electron block layer comprises a third block sublayer and a fourth block sublayer,
the second electron block layer is located between the second light emitting layer and the second hole transport layer, and
a difference between a HOMO energy level of the material of the third hole sublayer and a LUMO energy level of the second electron block layer is less than or equal to 0.4 eV.

13. The organic light emitting device according to claim 12, wherein a mobility of the material of the third hole sublayer is greater than a mobility of the second electron block layer.

14. The organic light emitting device according to claim 12, wherein a difference between a LUMO energy level of the fourth block sublayer and a HOMO energy level of the second light emitting layer is less than or equal to 0.4 eV.

15. The organic light emitting device according to claim 12, wherein
the second electron block layer comprises a third block sublayer, or
the second electron block layer comprises a third block sublayer and a fourth block sublayer, the fourth block sublayer is located between the third block sublayer and the second light emitting layer, and a material of the third block sublayer is different from a material of the fourth block sublayer.

16. The organic light emitting device according to claim 1, wherein the compound of Formula 1 is selected from one or more of the following compounds:

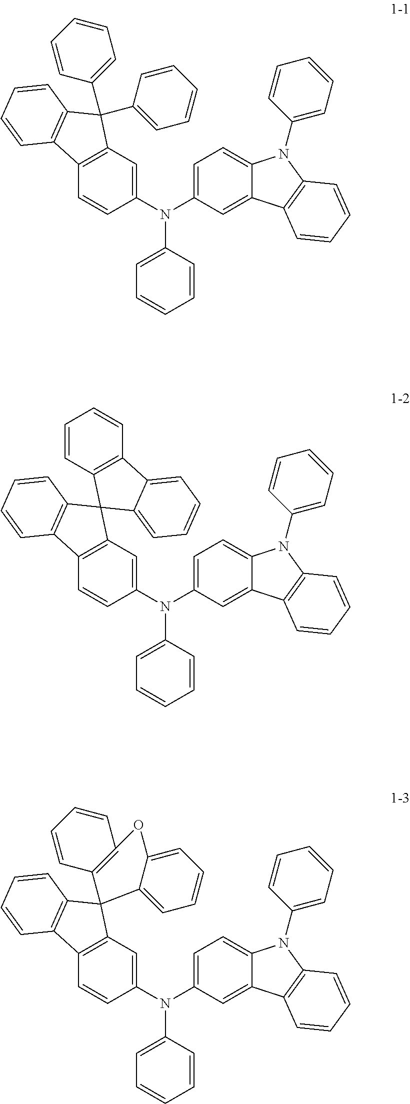 [SMILES: c1ccc(N(c2ccc3c(c2)C(c2ccccc2)(c2ccccc2)c2ccccc2-3)c2ccc3c(c2)c2ccccc2n3-c2ccccc2)cc1 ; c1ccc(N(c2ccc3c(c2)C2(c4ccccc4-c4ccccc42)c2ccccc2-3)c2ccc3c(c2)c2ccccc2n3-c2ccccc2)cc1 ; c1ccc(N(c2ccc3c(c2)C2(c4ccccc4Oc4ccccc42)c2ccccc2-3)c2ccc3c(c2)c2ccccc2n3-c2ccccc2)cc1]

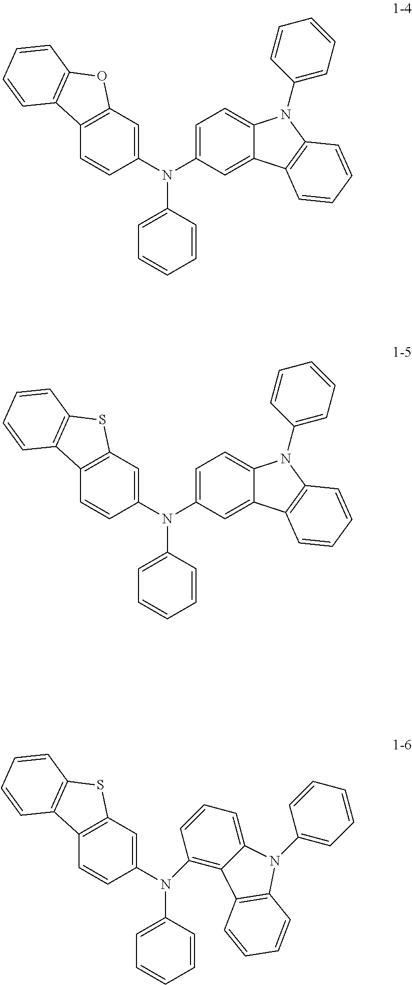 [SMILES: c1ccc(N(c2ccc3c(c2)oc2ccccc23)c2ccc3c(c2)c2ccccc2n3-c2ccccc2)cc1 ; c1ccc(N(c2ccc3c(c2)sc2ccccc23)c2ccc3c(c2)c2ccccc2n3-c2ccccc2)cc1 ; c1ccc(N(c2ccc3c(c2)sc2ccccc23)c2cccc3c2c2ccccc2n3-c2ccccc2)cc1]

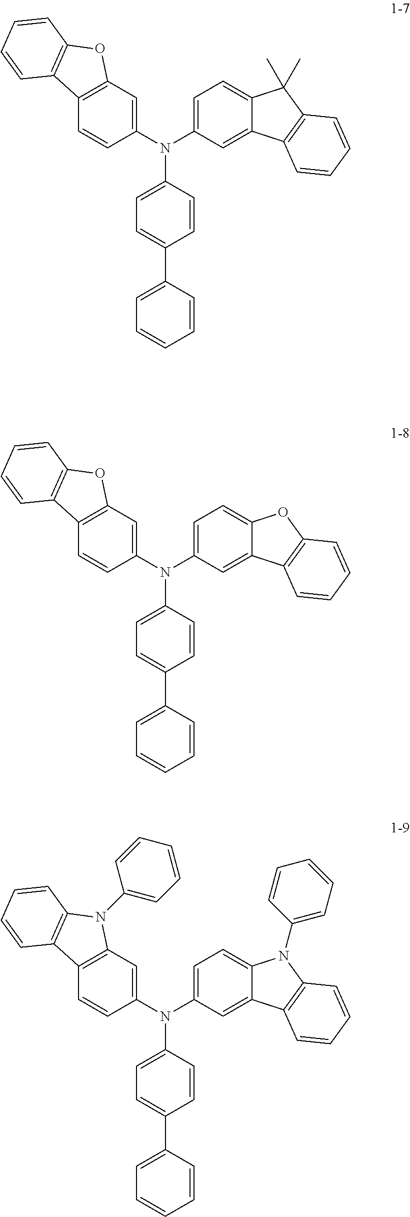 [SMILES: CC1(C)c2ccccc2-c2cc(N(c3ccc(-c4ccccc4)cc3)c3ccc4c(c3)oc3ccccc34)ccc21 ; c1ccc(-c2ccc(N(c3ccc4c(c3)oc3ccccc34)c3ccc4oc5ccccc5c4c3)cc2)cc1 ; c1ccc(-c2ccc(N(c3ccc4c(c3)c3ccccc3n4-c3ccccc3)c3ccc4c5ccccc5n(-c5ccccc5)c4c3)cc2)cc1]

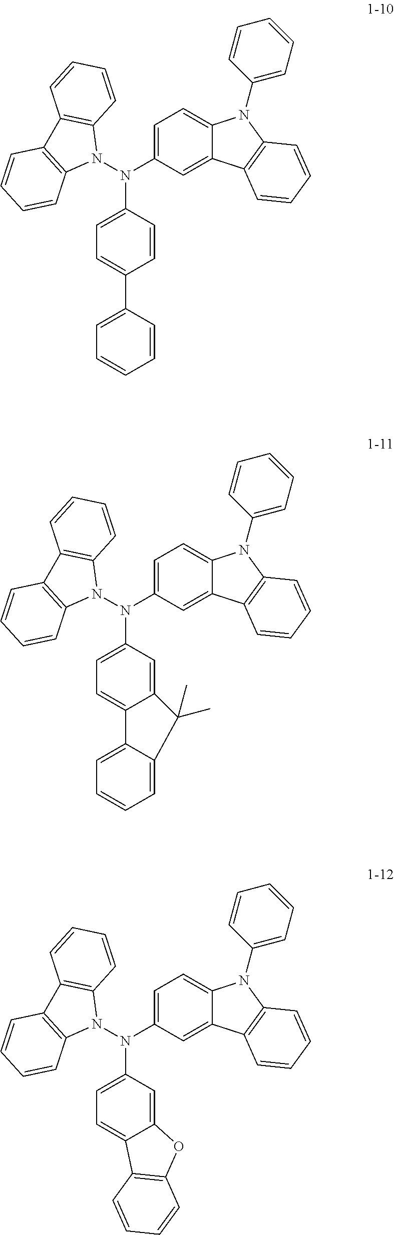 [SMILES: c1ccc(-c2ccc(N(c3ccc4c(c3)c3ccccc3n4-c3ccccc3)n3c4ccccc4c4ccccc43)cc2)cc1 ; CC1(C)c2ccccc2-c2ccc(N(c3ccc4c(c3)c3ccccc3n4-c3ccccc3)n3c4ccccc4c4ccccc43)cc21 ; c1ccc(-n2c3ccccc3c3cc(N(c4ccc5c(c4)oc4ccccc45)n4c5ccccc5c5ccccc54)ccc32)cc1]

17. The organic light emitting device according to claim 1, wherein the second material comprises, but is not limited to, a compound having a structure of formula 3: 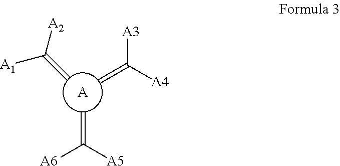
in Formula 3:
A1-A6 are each independently a halogen, substituted or unsubstituted cyano, substituted or unsubstituted aryl, substituted or unsubstituted heteroaryl, and aryl substituted by an electron-deficient group or heteroaryl substituted by an electron-deficient group; and
A is a three-membered ring, a four-membered ring, a five-membered ring, or a six-membered ring.

18. The organic light emitting device according to claim 17, wherein the compound of Formula 3 is selected from one or more of the following compounds:

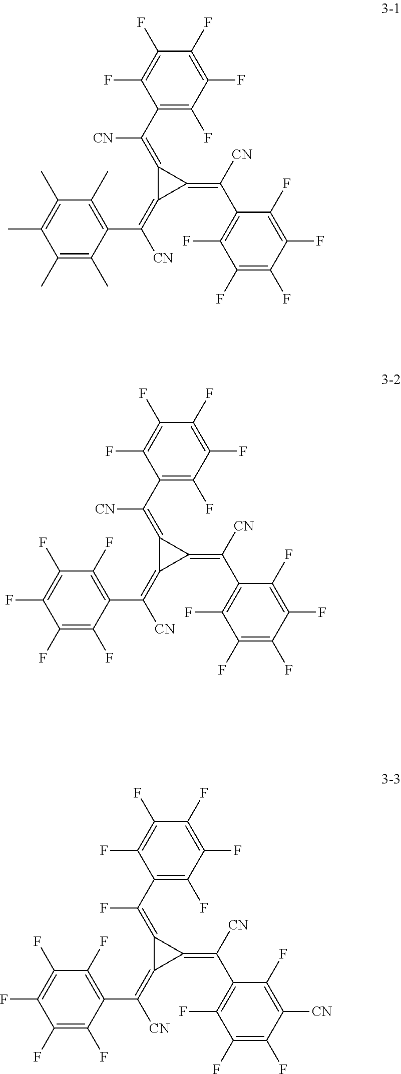

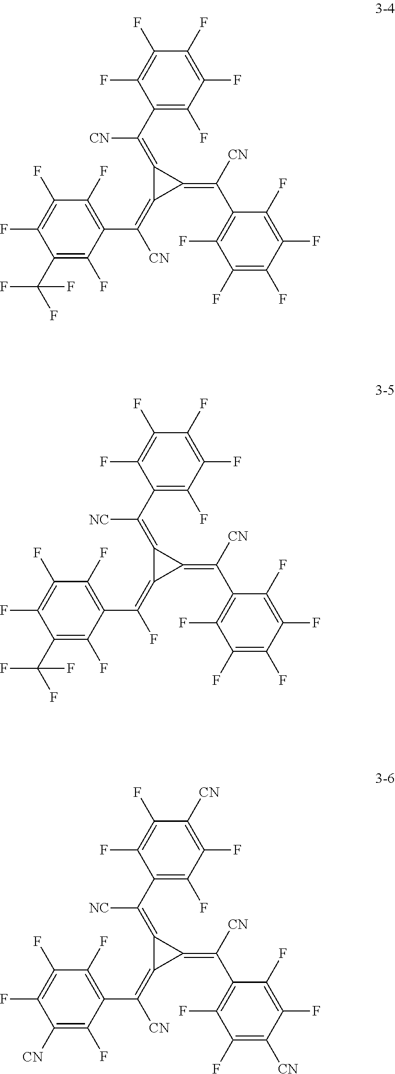

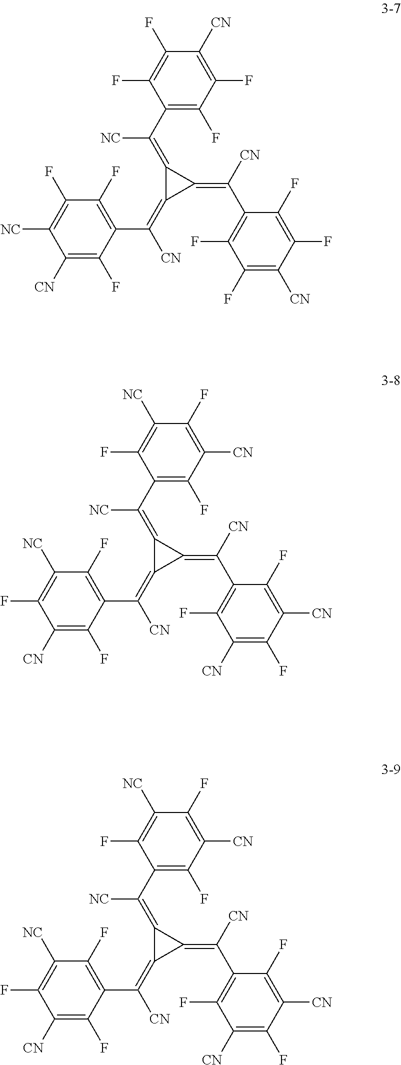

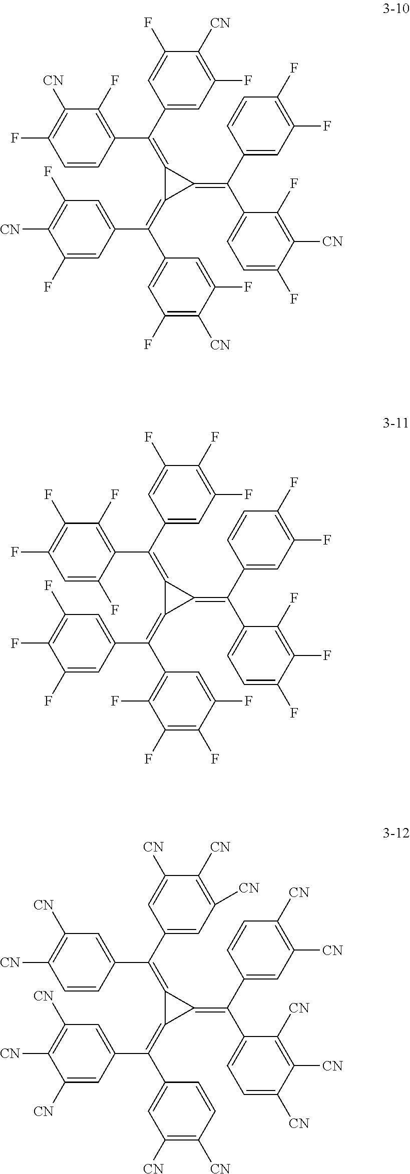

19. The organic light emitting device according to claim 4, wherein the electron block layer comprises, but is not limited to, a compound having a structure of Formula 4: 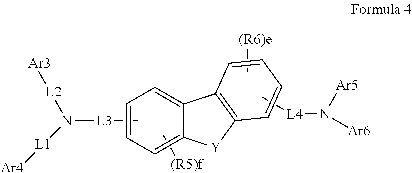
in Formula 4, Ar3, Ar4, Ar5 and Ar6 are each independently substituted or unsubstituted aryl, substituted or unsubstituted heteroaryl;
L1, L2, L3 and L4 are each independently a direct bond, each independently substituted or unsubstituted C6-C60 aryl;
R5 and R6 are each independently selected from deuterium, a halogen group, cyano, C3-C20 heteroaryl, C6-C20 aryl, C3-C12 trialkylsilyl, C18-C30 triarylsilyl, C1-C5 alkyl, C1-C10 haloalkyl, C3-C10 cycloalkyl, C2-C10 heterocycloalkyl, C5-C10 cycloalkenyl, C4-C10 heterocycloalkenyl, C1-C10 alkoxy, C1-C10 alkylthio, C6-C18 aryloxy, C6-C18 arylthio, C6-C24 phosphoroxy, C6-C18 alkylsulfonyl, C3-C18 trialkylphosphine, C3-C18 trialkylboron; or optionally bonded to adjacent groups to form a ring; and
Ar3, Ar4, Ar5 and Ar6 are each independently the following groups:

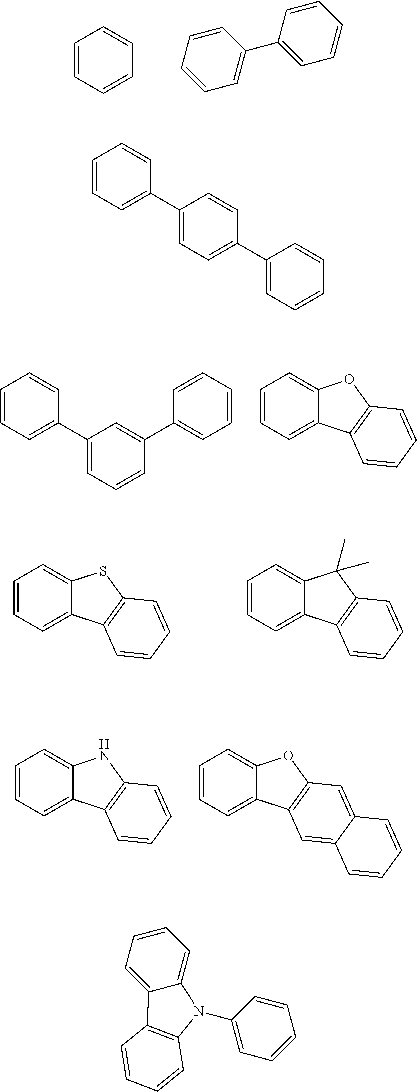

20. A display apparatus, comprising the organic light emitting device according to claim 1.
